(19) United States
(12) Patent Application Publication
(10) Pub. No.: US 2026/0255716 A1
(43) Pub. Date: Aug. 27, 2026

(54) IMAGE SENSOR

(71) Applicant: SAMSUNG ELECTRONICS CO., LTD., Suwon-si (KR)

(72) Inventor: HYOUN-JEE HA, Suwon-si (KR)

(73) Assignee: SAMSUNG ELECTRONICS CO., LTD., Suwon-si (KR)

(21) Appl. No.: 19/460,905

(22) Filed: Jan. 27, 2026

(30) Foreign Application Priority Data
Feb. 24, 2025 (KR) 10-2025-0023617

(51) Int. Cl. H10F 39/00

(52) U.S. Cl. CPC H10F 39/811; H10F 39/8037; H10F 39/807; H10F 39/809

(57) ABSTRACT

Provided is an image sensor, including a first semiconductor substrate, a second semiconductor substrate on the first semiconductor substrate, a floating diffusion region in the first semiconductor substrate, a contact plug between the first semiconductor substrate and the second semiconductor substrate, and connected with the floating diffusion region, a through plug penetrating through the second semiconductor substrate and connected with the contact plug, a pixel transistor on the second semiconductor substrate, and an upper connection pattern connecting the through plug with the pixel transistor on the second semiconductor substrate, wherein the upper connection pattern contacts a first surface of the through plug.

### CROSS-REFERENCE TO RELATED APPLICATIONS

This application claims priority to Korean Patent Application No. 10-2025-0023617, filed on February 24, 2025, in the Korean Intellectual Property Office, the disclosure of which is incorporated herein in its entirety by reference.

### BACKGROUND

Embodiments of the present disclosure relate to an image sensor, and in particular, to an image sensor with improved electrical and optical characteristics.

An image sensor is a device that converts optical signals into electrical signals. With the recent development of the computer and communication industries, there is an increasing demand for high-performance image sensors in a variety of applications such as digital cameras, camcorders, personal communication systems, gaming machines, security cameras, micro-cameras for medical applications, and/or robots.

The image sensors are generally classified into charge-coupled device (CCD) and complementary metal-oxide semiconductor (CMOS) image sensors. Since CMOS image sensors enable integration of a signal processing chip into a single chip, products of CMOS image sensors may be reduced in size. CMOS image sensors have very low power consumption and thus can be applicable to products with a limited battery capacity. Furthermore, since CMOS image sensors are compatible with CMOS process technology, the manufacturing cost of CMOS image sensors may be reduced. Therefore, the use of CMOS image sensors is rapidly increasing since high-resolution CMOS image sensors can be achieved with the development of technology.

### SUMMARY

One or more embodiments provide an image sensor with improved electrical and optical characteristics.

According to an aspect of one or more embodiments, there is provided an image sensor, including a first semiconductor substrate, a second semiconductor substrate on the first semiconductor substrate, a floating diffusion region in the first semiconductor substrate, a contact plug between the first semiconductor substrate and the second semiconductor substrate, and connected with the floating diffusion region, a through plug penetrating through the second semiconductor substrate and connected with the contact plug, a pixel transistor on the second semiconductor substrate, and an upper connection pattern connecting the through plug with the pixel transistor on the second semiconductor substrate, wherein the upper connection pattern contacts a first surface of the through plug.

According to another aspect of one or more embodiments, there is provided an image sensor, including a first semiconductor substrate, a second semiconductor substrate on the first semiconductor substrate, a floating diffusion region in the first semiconductor substrate, a lower connection pattern on the first semiconductor substrate and in contact with the floating diffusion region, a contact plug between the first semiconductor substrate and the second semiconductor substrate, and connected with the lower connection pattern, a through plug penetrating the second semiconductor substrate and connected with the contact plug, a through insulation pattern penetrating the second semiconductor substrate and on a sidewall of the through plug, a source follower gate electrode on the second semiconductor substrate, and an upper connection pattern contacting a first surface of the through plug and a first surface of the source follower gate electrode.

According to still another aspect of one or more embodiments, there is provided an image sensor, including a first semiconductor substrate, a second semiconductor substrate on the first semiconductor substrate, an isolation structure in the first semiconductor substrate and defining pixel regions, photodiode regions in the pixel regions in the first semiconductor substrate, respectively, floating diffusion regions in each of the pixel regions in the first semiconductor substrate, respectively, transfer gate electrodes respectively between the photodiode regions and the floating diffusion regions, a lower connection pattern contacting the floating diffusion regions in at least two pixel regions of the pixel regions adjacent to each other, a contact plug between the first semiconductor substrate and the second semiconductor substrate, and connected with the lower connection pattern, a through plug penetrating through the second semiconductor substrate and connected with the contact plug, a through insulation pattern penetrating the second semiconductor substrate and on a sidewall of the through plug, a pixel transistor on the second semiconductor substrate, and an upper connection pattern connecting the through plug and the pixel transistor, wherein the upper connection pattern is in contact with a first surface of the through plug.

According to further still another aspect of one or more embodiments, there is provided a method of fabricating an image sensor including forming an isolation structure defining pixel regions in a first semiconductor substrate, forming floating diffusion regions in the pixel regions of the first semiconductor substrate, respectively, forming a lower connection pattern in contact with the floating diffusion regions of at least two of the pixel regions of the pixel regions adjacent to each other, forming a lower insulating layer on the first semiconductor substrate, forming a contact plug penetrating through the lower insulating layer and connected to the lower connection pattern, forming a second semiconductor substrate on the lower insulating layer, forming a through insulation pattern penetrating the second semiconductor substrate and exposing a first surface of the contact plug, forming a through plug connected with the contact plug in the through insulation pattern, forming a pixel transistor on the first surface of the second semiconductor substrate, and forming an upper connection pattern contacting the first surface of through plug and connected with the pixel transistor.

Forming the through insulation pattern may include patterning the second semiconductor substrate to form a through hole exposing a first surface of the contact plug, forming an insulating layer on an inner wall of the through hole with a uniform thickness, and etching the insulating layer to expose a part of the first surface of the connection plug.

The through insulation pattern may be formed of a low-k dielectric material having a dielectric constant lower than a dielectric constant of silicon oxide.

Prior to forming the contact plug, the method may further include forming a contact hole penetrating through the lower insulating layer to expose a part of the lower connection pattern, and doping an impurity of a first conductivity type with a first surface of the lower connection patterns exposed in the contact hole to form a first doped region in the lower connection pattern.

Prior to forming the through plug, the method may further include doping an impurity of a first conductivity type into a first surface of the contact plug exposed by the through insulation pattern to form a second doped region in the contact plug.

Prior to forming the upper connection pattern, the method may further include doping an impurity of a first conductivity type into a first surface of the through plug to form a third doped region in the through plug.

Prior to forming the through insulation pattern, the method may further include forming a device isolation pattern defining an active portion in the second semiconductor substrate. The through insulation pattern may penetrate a portion of the device isolation pattern.

Forming the pixel transistor may include forming a pixel gate electrode on the active portion of the second semiconductor substrate, and forming source and drain regions in the active portion at opposite sides of the pixel gate electrode. The upper connection pattern may be in contact with a first surface of the pixel gate electrode.

Prior to forming the lower connection pattern, the method may further include forming a photoelectric conversion region in the first semiconductor substrate, in each of the pixel regions, and forming a transfer gate electrode between the floating diffusion region and the photodiode region, in each of the pixel regions.

### BRIEF DESCRIPTION OF DRAWINGS

Embodiments will be more clearly understood from the following detailed description taken in conjunction with the accompanying drawings in which:

FIG. 1 is a block diagram of an image sensor according to one or more embodiments;

FIGS. 2A and 2B are circuit diagrams of unit pixels of an image sensor according to one or more embodiments;

FIG. 3 is a plan view illustrating a portion of an image sensor according to one or more embodiments;

FIG. 4 is a schematic cross-sectional view of an image sensor of FIG. 3taken along line I-I’ shown in FIG. 3;

FIG. 5 is an enlarged sectional view illustrating a portion ‘P’ of FIG. 4;

FIGS. 6, 7, 8, and 9 are sectional views illustrating an image sensor according to one or more embodiments;

FIG. 10 is a schematic plan view illustrating a portion of an image sensor according to one or more embodiments;

FIG. 11 is a cross-sectional view schematically illustrating the image sensor of FIG. 10taken along line I-I’ shown in FIG. 10;

FIG. 12 is a schematic plan view illustrating a portion of an image sensor according to one or more embodiments;

FIG. 13 is a schematic cross-sectional view of an image sensor of FIG. 12 taken along line I-I’ shown in FIG. 12;

FIG. 14 is a schematic cross-sectional view of an image sensor according to one or more embodiments;

FIGS. 15, 16, 17, 18, and 19 are sectional views to illustrate a method of fabricating an image sensor according to one or more embodiments;

FIG. 20 is a plan view schematically illustrating an image sensor according to one or more embodiments; and

FIGS. 21 and 22 are sectional views, which are taken along a line I-I' of FIG. 20 to illustrate an image sensor according to one or more embodiments.

### DETAILED DESCRIPTION

Embodiments will now be described more fully with reference to the accompanying drawings. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

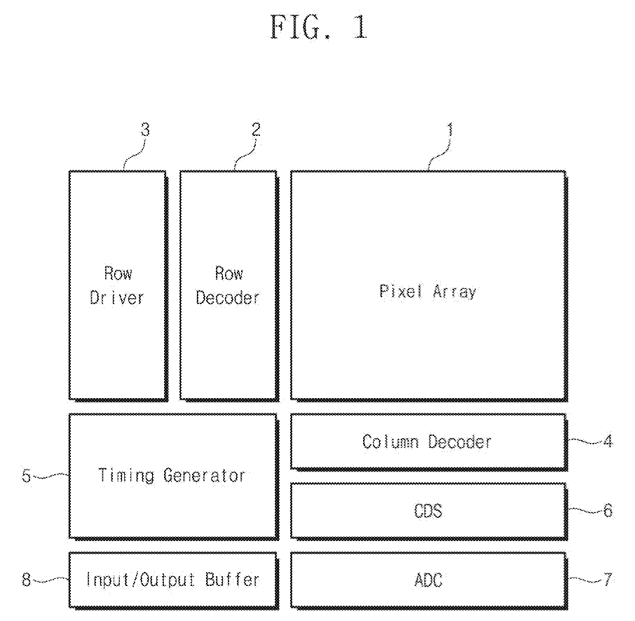

FIG. 1 is a block diagram of an image sensor according to one or more embodiments.

Referring to FIG. 1, an image sensor may include an active pixel sensor array 1, a row decoder 2, a row driver 3, a column decoder 4, a timing generator 5, a correlated double sampler (CDS) 6, an analog-to-digital converter (ADC) 7, and an input/output buffer 8.

The active pixel sensor array 1 may include a plurality of two-dimensionally arranged unit pixels, each of which is configured to convert optical signals into electrical signals. The active pixel sensor array 1 may be driven by a plurality of driving signals such as a pixel selection signal, a reset signal, and a charge transfer signal from the row driver 3. The converted electrical signals may be provided for the correlated double sampler 6.

The row decoder 2 may provide the driving signals to the unit pixels of each row. In addition, electrical signals converted in the active pixel sensor array 1 may be provided to the correlated double sampler 6 in response to the driving signals.

The row driver 3 may provide the active pixel sensor array 1 with several driving signals for driving several unit pixels in accordance with a decoded result obtained from the row decoder 2. When the unit pixels are arranged in a matrix shape, the driving signals may be provided for respective rows.

The timing generator 5 may control the row and column decoders 2 and 4, the correlated double sampler 6, the analog-to-digital converter 7, and the input/output buffer 8 and may supply control signals (e.g., a clock signal, a timing control signal, etc.) in operation thereof. The timing generator 5 may include a logic control circuit, a phase lock loop (PLL) circuit, a timing control circuit, and a communication interface circuit.

The correlated double sampler (CDS) 6 may receive the electrical signals generated in the active pixel sensor array 1, and may hold and sample the received electrical signals. The correlated double sampler 6 may perform a double sampling operation to sample a specific noise level and a signal level of the electrical signal, and then output a difference level corresponding to a difference between the noise and signal levels.

The analog-to-digital converter (ADC) 7 may convert analog signals, which correspond to the difference level received from the correlated double sampler 6, into digital signals and then output the converted digital signals.

The input/output buffer 8 may latch the digital signals and then sequentially output the latched digital signals to an image signal processing unit in response to the decoded result obtained from the column decoder 4.

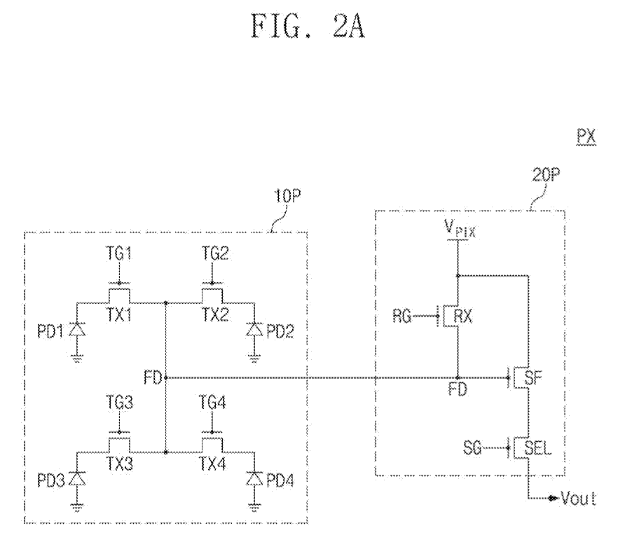

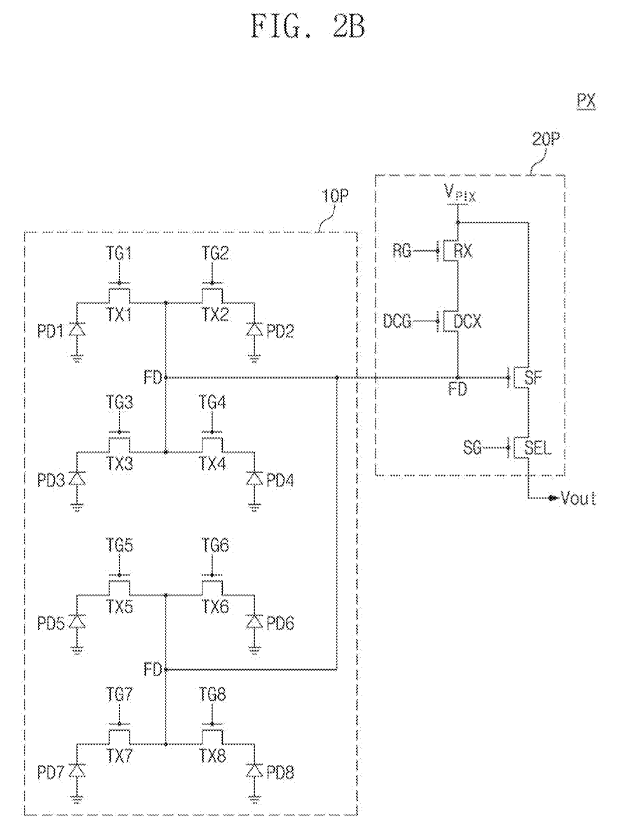

FIGS. 2A and 2B are circuit diagrams of unit pixels of an image sensor according to one or more embodiments.

Referring to FIG. 2A, the unit pixel PX may include a photoelectric conversion circuit 10P and a pixel circuit 20P.

The photoelectric conversion circuit 10P may include a first photodiode PD1, a second photodiode PD2, a third photodiode PD3, and a fourth photodiode PD4, a first transfer transistor TX1, a second transfer transistor TX2, a third transfer transistor TX3, and a fourth transfer transistor TX4, and a floating diffusion region (or a charge detection node; FD).

The first to fourth transfer transistors TX1 to TX4 may transfer the charge accumulated in the first to fourth photodiodes PD1 to PD4 to the floating diffusion region FD. The first to fourth transfer transistors TX1 to TX4 may share the floating diffusion region FD. The transfer gate electrodes of the first to fourth transfer transistors TX1 to TX4 may be controlled by first to fourth transfer signals TG1, TG2, TG3, and TG4.

For example, the first to fourth photodiodes PD1 to PD4 may generate and accumulate electric charges corresponding to incident light. The first and second photodiodes PD1 and PD2 may be, for example, photo diodes, photo transistors, photo gates, pinned photo diodes (PPDs) and combinations thereof.

The floating diffusion region FD may receive charges generated in at least one of the first to fourth photodiodes PD1 to PD4 and may cumulatively store the charges. A source follower transistor SF may be controlled according to the amount of photo charges accumulated in the floating diffusion region FD.

The pixel circuit 20P may include a reset transistor RX, a source follower transistor SF, and a selection transistor SX. In some embodiments, each unit pixel PX may include three pixel transistors, but embodiments are not limited thereto, and the number of pixel transistors in each unit pixel PX may be variously changed.

For example, the reset transistor RX may periodically reset the charges accumulated in the floating diffusion region FD by a reset signal RG applied to a reset gate electrode. For example, the reset transistor RX may include a source terminal, which is connected to a dual conversion gain transistor DCX or the floating diffusion region FD, and a drain terminal, which is connected to a power supply voltage V_{PIX}. When the reset transistor RX is turned on, the power supply voltage V_{PIX} may be transferred to the floating diffusion region FD. Accordingly, the charges accumulated in the floating diffusion region FD may be discharged to reset the floating diffusion region FD.

The source follower transistor SF may be a source follower amplifier that generates a source-drain current in proportion to the amount of charge in the floating diffusion region FD input to the source follower gate electrode. The source follower transistor SF may amplify a change in electric potential of the floating diffusion region FD and may output the amplified signal to the output line Vout through the selection transistor SX. A drain terminal of the source follower transistor SF may be connected to the power supply voltage V_{PIX}, and a source terminal of the source following transistor SF may be coupled to a drain terminal of the selection transistor SX.

The selection transistor SX may be used to select a row of unit pixels PX to be read out during a reading operation. When the selection transistor SX is turned on by the selection signal SG applied to the selection gate electrode, an electrical signal output to the source electrode of the source follower transistor SF may be output to the output line Vout.

Referring to FIG. 2B, the unit pixel PX may include a photoelectric conversion circuit 10P and a pixel circuit 20P, as described with reference to FIG. 2A. The photoelectric conversion circuit 10P may include a first photodiode PD1, a second photodiode PD2, a third photodiode PD3, a fourth photodiode PD4, a fifth photodiode PD5, a sixth photodiode PD6, a seventh photodiode PD7, and an eighth photodiode PD8, a first transfer transistor TX1, a second transfer transistor TX2, a third transfer transistor TX3, a fourth transfer transistor TX4, a fifth transfer transistor TX5, a sixth transfer transistor TX6, a seventh transfer transistor TX7, and an eighth transfer transistor TX8, and a floating diffusion region FD.

The first to eighth transfer transistors TX1 to TX8 may share the floating diffusion region FD. The transfer gate electrodes of the first to eighth transfer transistors TX1 to TX8 may be controlled by first to eighth transfer signals TG1 to TG8.

The pixel circuit 20P may include a reset transistor RX, a source follower transistor SF, and a selection transistor SX, and may further include a dual conversion gain transistor DCX, as described above with reference to FIG. 2A.

The dual conversion gain transistor DCX may be coupled between the reset transistor RX and the floating diffusion region FD. The power supply voltage V_{PIX} may be transferred to the floating diffusion region FD when the reset transistor RX and the dual conversion gain transistor DCX are turned on. Thus, the charges accumulated in the floating diffusion region FD may be discharged to reset the floating diffusion region FD.

The dual conversion gain transistor DCX may change the capacitance of the floating diffusion region FD in response to the dual conversion gain control signal DCG, thereby changing the conversion gain of the unit pixel PX.

For example, when capturing an image, high illuminance light and low illuminance light may be simultaneously incident on a pixel array, or strong light and weak light may be simultaneously incident on a pixel array. The dual conversion gain transistor DCX may be turned on in the high illumination mode and turned off in the low illumination mode. Due to the dual conversion gain transistor DCX, it may be possible to realize different conversion gains in the high and low illumination modes.

When the dual conversion gain transistor DCX is turned on, the capacitance of the floating diffusion region FD may increase and thus the conversion gain may decrease. When the dual conversion gain transistor DCX is turned off, the capacitance of the floating diffusion region FD may decrease and thus the conversion gain may increase.

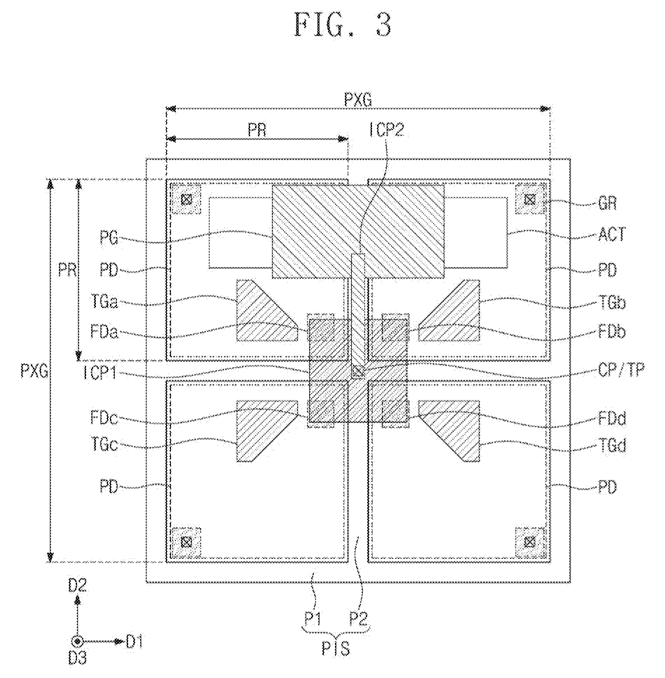

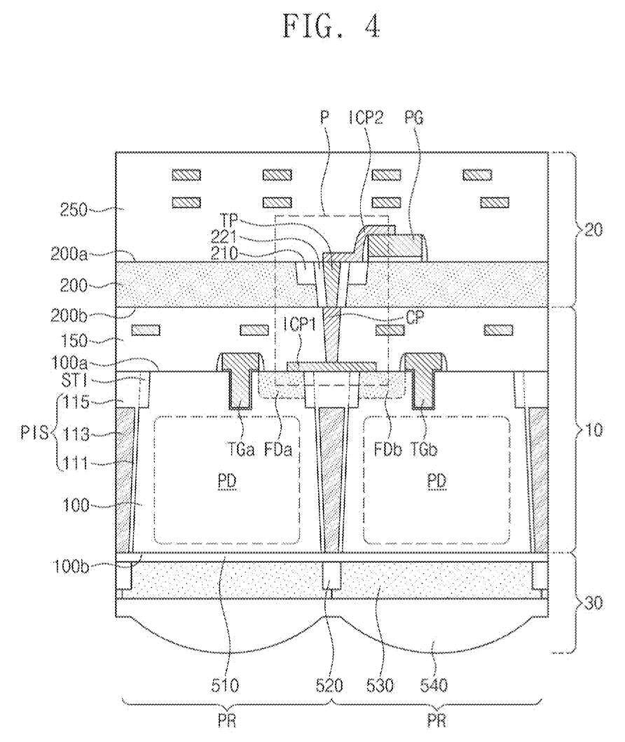

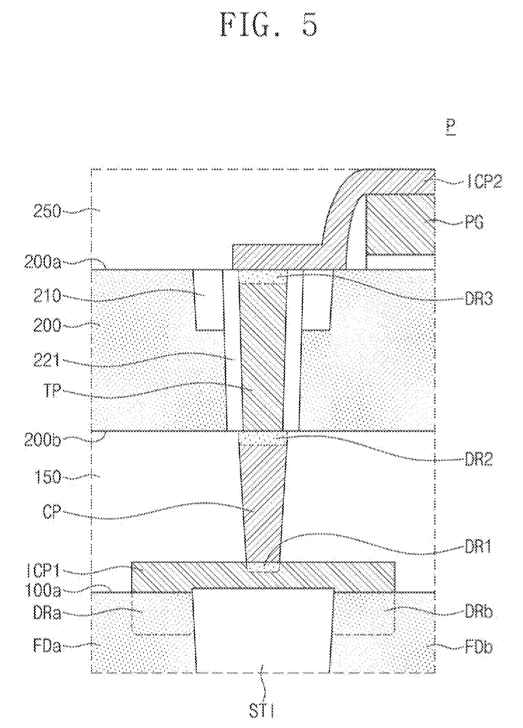

FIG. 3 is a plan view illustrating a portion of an image sensor according to one or more embodiments. FIG. 4 is a schematic cross-sectional view of an image sensor of FIG. 3 taken along line I-I’ shown in FIG. 3. FIG. 5 is an enlarged sectional view illustrating a portion ‘P’ of FIG. 4.

Referring to FIGS. 3 and 4, an image sensor according to one or more embodiments may include a photoelectric conversion circuit layer 10, a pixel circuit layer 20, and a light transmissive layer 30.

The photoelectric conversion circuit layer 10 may be disposed between the pixel circuit layer 20 and the light transmissive layer 30 when viewed in the cross-sectional view as shown in FIG. 4. The photoelectric conversion circuit layer 10 may include a first semiconductor substrate 100, an isolation structure PIS, a photoelectric conversion region PD, transfer gate electrodes TGa, TGb, TGc, and TGd, floating diffusion regions FDa, FDb, FDc, and FDd, and a first interlayer insulating layer 150.

The first semiconductor substrate 100 may have a first surface 100a (or frontside surface) and a second surface 100b (or backside surface), which are opposite to each other. The first semiconductor substrate 100 may be a substrate in which a first-conductive type (e.g., p-type) epitaxial layer is formed on a first-conductive type bulk silicon substrate, and may be a substrate in which a bulk silicon substrate has been removed and a p-type epitaxial layer remains during a manufacturing process of an image sensor. As another example, the first semiconductor substrate 100 may be a bulk semiconductor substrate including a well of the first conductivity type.

The first semiconductor substrate 100 may include a plurality of pixel groups PXG. Each of the pixel groups PXG may include at least 4, 8, or 16 pixel regions PR. In each pixel group PXG, the pixel regions PR may be arranged in a first direction D1 and a second direction D2, which are not parallel to each other, or in a matrix shape. Each of the pixel regions PR may be defined by an isolation structure PIS provided in the first semiconductor substrate 100.

The isolation structure PIS may include first portions P1 extending along the first direction D1 and second portions P2 extending along the second direction D2. The isolation structure PIS may surround and/or be adjacent to each of the pixel regions PR, when viewed in a top plan view from the vertical direction (third direction D3).

In one or more embodiments, the isolation structure PIS may penetrate the first semiconductor substrate 100. For example, the isolation structure PIS may have a length in a direction (i.e., a third direction D3), which is perpendicular to the top surface of the first semiconductor substrate 100, and the length of the isolation structure PIS may be substantially the same as the vertical thickness of the first semiconductor substrate 100. In another example, the isolation structure PIS may be vertically extended from the first surface 100a to the second surface 100b of the first semiconductor substrate 100, and may be spaced apart from the second surface 100b of the first semiconductor substrate 100.

The width of the isolation structure PIS in the first direction D1 and/or second direction D2 may gradually decrease from the first surface 100a to the second surface 100b of the first semiconductor substrate 100. As another example, the width of the isolation structure PIS may gradually increase from the first surface 100a to the second surface 100b of the first semiconductor substrate 100 in the first direction D1 and/or second direction D2.

In one or more embodiments, the isolation structure PIS may include a liner insulation pattern 111, a gap-fill pattern 113, and a capping insulation pattern 115. The gap-fill pattern 113 may vertically penetrate a portion of the first semiconductor substrate 100, and the liner insulation pattern 111 may be provided between the gap-fill pattern 113 and the first semiconductor substrate 100. The capping insulation pattern 115 may be disposed on the gap-fill pattern 113. The liner insulation pattern 111 and the capping insulation pattern 115 may include at least one of a silicon oxide layer, a silicon oxynitride layer, and a silicon nitride layer. The gap-fill pattern 113 may include an undoped polysilicon layer or a doped polysilicon layer. The gap-fill pattern 113 may include an air gap or void. The capping insulation pattern 115 of the isolation structure PIS may include the same insulating material as a shallow trench isolation pattern STI, and in this case, there may be no visible or observable boundary between the capping insulation pattern 115 and the shallow trench isolation pattern STI.

The photodiode PD regions may be respectively provided in the pixel regions PR of the first semiconductor substrate 100. An incident light may be converted to electrical signals in the photodiode PD regions. The photodiode PD regions may be formed by ion-implanting impurities of a second conductivity type opposite to the first conductivity type of the first semiconductor substrate 100 into the first semiconductor substrate 100. For example, a junction serving as a photodiode may be formed by the first semiconductor substrate 100 of the first conductivity type and the photodiode PD regions.

According to some embodiments, the photodiode PD regions may have a difference in impurity concentration between a region adjacent to the first surface 100a and a region adjacent to the second surface 100b so as to have a potential gradient between the first and second surfaces 100a and 100b of the first semiconductor substrate 100. For example, the photodiode PD regions may include a plurality of impurity regions vertically stacked.

The shallow trench isolation pattern STI may be disposed to be adjacent to the first surface 100a of the first semiconductor substrate 100 in each of the pixel regions PR. The shallow trench isolation pattern STI may define an active portion on the first surface 100a of the first semiconductor substrate 100. The shallow trench isolation pattern STI may be provided in a device isolation trench formed by recessing the first surface 100a of the first semiconductor substrate 100. The shallow trench isolation pattern STI may be formed of an insulating material.

The transfer gate electrodes TGa, TGb, TGc, or TGd may be provided in the pixel regions PR, respectively. The transfer gate electrodes TGa to TGd may be disposed on the first surface 100a of the first semiconductor substrate 100. The transfer gate electrodes TGa to TGd may overlap the photodiode PD regions, when viewed in a top plan view. The transfer gate electrodes TGa to TGd may be disposed in the first semiconductor substrate 100. The transfer gate electrodes TGa to TGd may include a lower portion inserted into the first semiconductor substrate 100 and an upper portion connected with the lower portion and protruding above the first surface 100a of the first semiconductor substrate 100. The lower portion of the transfer gate electrodes TGa to TGd may vertically penetrate a portion of the first semiconductor substrate 100. The bottom surface of the transfer gate electrodes TGa to TGd may be located at a lower level in the third direction D3 than the first surface 100a of the first semiconductor substrate 100. A gate insulating layer may be interposed between the transfer gate electrodes TGa to TGd and the first semiconductor substrate 100.

The floating diffusion regions FDa to FDd may be provided in the first semiconductor substrate 100 in the pixel regions PR, respectively. The floating diffusion regions FDa to FDd may be adjacent to the shallow trench isolation pattern STI. In each pixel region PR, the floating diffusion regions FDa to FDd may overlap a portion of the photoelectric conversion region PD in the vertical direction (third direction D3).

The floating diffusion regions FDa to FDd may be formed by ion-implanting dopants of a second conductivity type opposite to that of the first semiconductor substrate 100. For example, the floating diffusion regions FDa to FDd may be n-type dopant regions.

Each of the floating diffusion regions FDa to FDd may include high doped regions DRa or DRb in contact with a lower connection pattern ICP1, as shown in FIG. 5. The dopant concentration of the high doped regions DRa and DRb may be greater than a dopant concentration of each of the floating diffusion regions FDa to FDd.

In each of the pixel regions PR, a ground impurity region GR may be provided in the first semiconductor substrate 100 and may be spaced apart from the transfer gate electrodes TGa to TGd. The ground impurity region GR may overlap a portion of the photodiode PD region in the vertical direction (third direction D3). The ground impurity region GR may be formed by an ion implantation process of injecting dopants of the same first conductivity type as the first semiconductor substrate 100. For example, the ground impurity region GR may be a p-type impurity region. A ground voltage may be applied to the first semiconductor substrate 100 through the ground impurity region GR.

According to one or more embodiments, the lower connection pattern ICP1 may be disposed on the first surface 100a of the first semiconductor substrate 100, and may be commonly connected to the floating diffusion regions FDa to FDd provided in the at least two pixel regions PR adjacent to each other. In one or more, the lower connection pattern ICP1 may be commonly connected to the floating diffusion regions FDa to FDd of the four pixel regions PR adjacent to each other. As another example, the lower connection pattern ICP1 may be commonly connected to 6, 8, 12, or the like floating diffusion regions adjacent to each other. The lower connection pattern ICP1 may be in direct contact with the floating diffusion regions FDa to FDd of the pixel regions PR.

The lower connection pattern ICP1 may be formed of conductive material. The lower connection pattern ICP1 may be formed of single-crystalline silicon or poly-crystalline silicon that is doped with dopants of the second conductivity type. Furthermore, the lower connection pattern ICP1 may be formed of or include at least one of metallic materials such as, for example, tungsten, titanium, tantalum, cobalt, or the like. For example, the lower connection pattern ICP1 may include poly-crystalline silicon doped with dopants of the second conductivity type, and a dopant concentration of the lower connection pattern ICP1 may be higher than a dopant concentration in the high doped regions DRa or DRb of the floating diffusion regions FDa to FDd.

The lower connection pattern ICP1 may be in direct contact with a top surface of the shallow trench isolation pattern STI and a part of a top surface of the isolation structure PIS. The lower connection pattern ICP1 may have a first thickness on the first surface 100a of the first semiconductor substrate 100, and each of the transfer gate electrodes TGa to TGd may have a second thickness on the first surface 100a of the first semiconductor substrate 100 in the third direction D3. Here, the second thickness may be greater than the first thickness.

Referring back to FIG. 5, the lowermost surface of the lower connection pattern ICP1 may be located at a lower level than the upper surface of the shallow trench isolation pattern STI in the third direction D3.

The first interlayer insulating layer 150 may cover and/or be provided on the transfer gate electrodes TGa to TGd on the first surface 100a of the first semiconductor substrate 100. The first interlayer insulating layer 150 may include a plurality of interlayer insulating layers stacked. The first interlayer insulating layer 150 may include, for example, silicon oxide, silicon nitride, and/or silicon oxynitride.

Conductive lines may be provided in the first interlayer insulating layer 150. The conductive lines may include, for example, metallic material such as tungsten, copper, aluminum, or an alloy thereof.

According to one or more embodiments, a contact plug CP may penetrate the first interlayer insulating layer 150 to be connected to the lower connection pattern ICP1. The lower connection pattern ICP1 may include a first doped region DR1 having a higher doping concentration and contacting the contact plug CP. The first doped region DR1 may include, for example, dopants of a second conductivity type (for example, n-type).

The contact plug CP may include a second doped region DR2 having a higher doping concentration and contacting a through plug TP in an upper portion of the contact plug CP. The second doped region DR2 may include dopants of the second conductivity type (e.g., n-type).

The contact plug CP may include a conductive material. The lower connection pattern ICP1 may be formed of single-crystalline silicon or polysilicon doped with a dopant of the second conductivity type. As another example, the contact plug CP may include a metal material such as, for example, tungsten, copper, aluminum, or an alloy thereof.

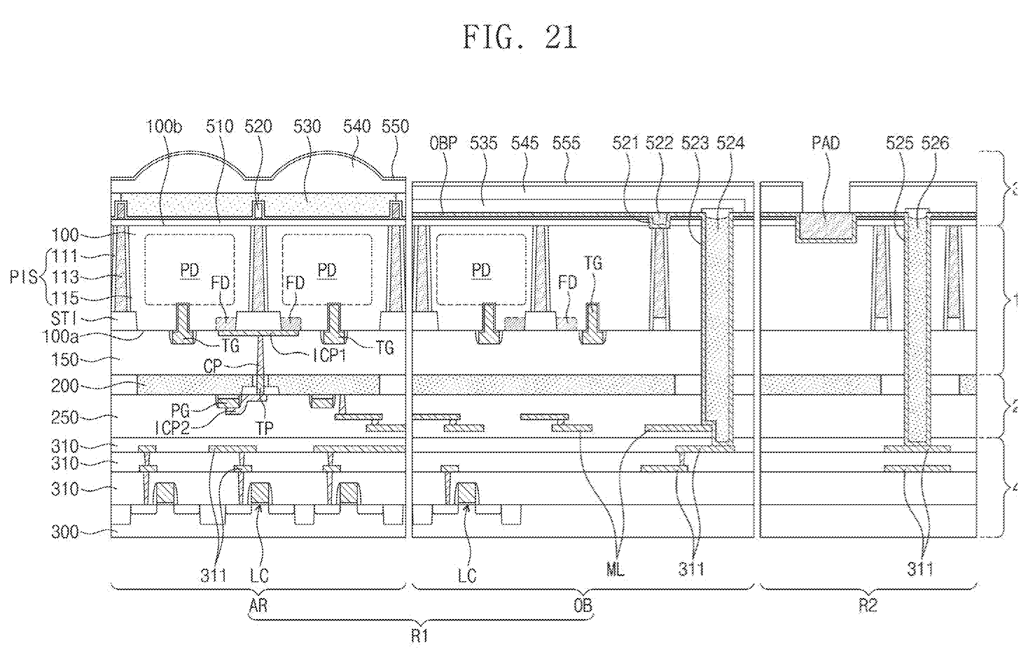

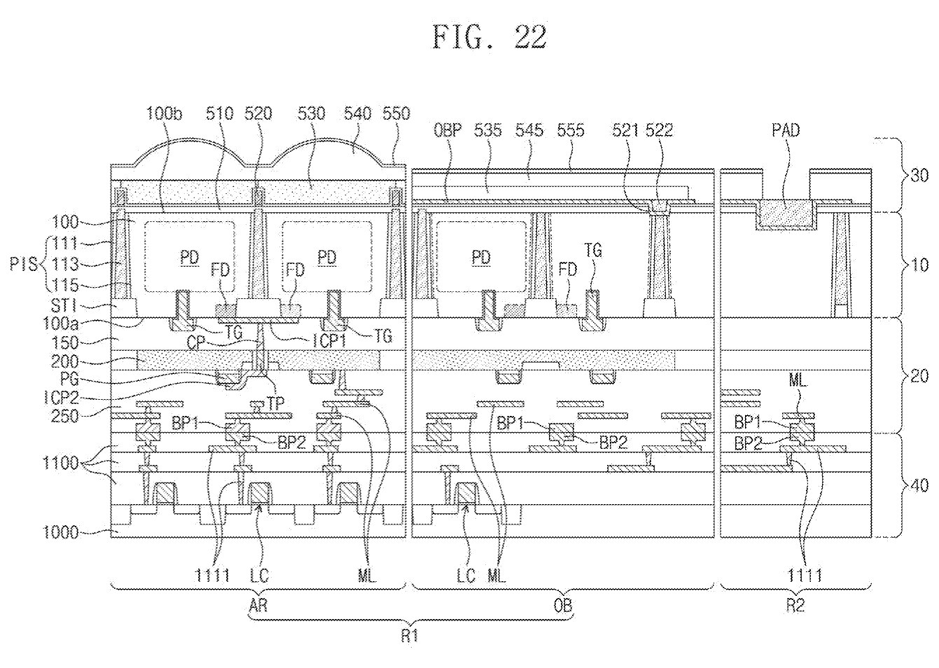

According to one or more embodiments, the pixel circuit layer 20 may be disposed on the first interlayer insulating layer 150 of the photoelectric conversion circuit layer 10. The pixel circuit layer 20 may include a pixel circuit 20P of the unit pixels PX (refer to FIGS. 2A and 2B). The pixel circuit layer 20 may be disposed between the photoelectric conversion circuit layer 10 and a logic circuit layer 40 (refer to FIGS. 21 and 22).

The pixel circuit layer 20 may include a second semiconductor substrate 200, the through plug TP, a through insulation pattern 221, and pixel transistors. The pixel transistors may include the source follower transistor SF, the reset transistor RX, the dual conversion gain transistor DCX, and the selection transistor SEL described above with reference to FIGS. 2A and 2B.

For example, the second semiconductor substrate 200 may have a first surface 200a and a second surface 200b opposite to each other. The second semiconductor substrate 200 may include a semiconductor material of a first conductivity type, for example, silicon, germanium, silicon-germanium. The second semiconductor substrate 200 may be a bulk substrate or an epitaxial layer.

The second surface 200b of the second semiconductor substrate 200 may be in contact with the first interlayer insulating layer 150.

A device isolation pattern 210 may be disposed in the second semiconductor substrate 200 and may define an active portion ACT. The device isolation pattern 210 may be disposed adjacent to the first surface 200a of the second semiconductor substrate 200. The device isolation pattern 210 may be formed of an insulating material. The device isolation pattern 210 may include, for example, silicon oxide, silicon nitride, and/or silicon oxynitride.

According to one or more embodiments, the through plug TP may penetrate the second semiconductor substrate 200 and be connected to the contact plug CP.

The through plug TP may penetrate the second semiconductor substrate 200 in each pixel group PXG. The through plug TP may electrically connect the photodiodes of the photoelectric conversion circuit layer 10 and the pixel transistors, e.g., source follower transistors, of the pixel circuit layer 20.

For example, the through plug TP may electrically connect the floating diffusion regions FDa to FDd of each pixel group PXG and the gate terminal of the source follower transistor. In one or more embodiments, the through plug TP may be provided in each of the pixel groups PXG, and each pixel group PXG may include four pixel regions PR. For example, the four pixel regions PR may share one through plug TP.

The through plug TP may penetrate the device isolation pattern 210 of the second semiconductor substrate 200.

The through plug TP may include a conductive material. The lower connection pattern ICP1 may be formed of single-crystalline silicon or polysilicon doped with a dopant of the second conductivity type. As another example, the through plug TP may include at least one of metallic materials such as, for example, tungsten, copper, aluminum, or an alloy thereof.

The diameter at the bottom surface of the through plug TP may be smaller than a diameter at the top surface of the contact plug CP.

The top surface of the through plug TP may be substantially coplanar with the first surface 200a of the second semiconductor substrate. A lower surface of the through plug TP may be substantially coplanar with the second surface 200b of the second semiconductor substrate 200.

Referring to FIG. 5, the through plug TP may include a third doped region DR3 having a relatively high impurity concentration and being in contact with an upper connection pattern ICP2. The third doped region DR3 may include, for example, a dopant of a second conductivity type (e.g., n-type).

The through insulation pattern 221 may penetrate the device isolation pattern 210 of the second semiconductor substrate 200. The through insulation pattern 221 may surround and/or be adjacent to a sidewall of the through plug TP. For example, the through insulation pattern 221 may be disposed between the through plug TP and the second semiconductor substrate 200. An upper surface of the through insulation pattern 221 may be substantially coplanar with the first surface 200a of the second semiconductor substrate 200, and a lower surface of the through insulation pattern 221 may also be substantially coplanar to the second surface 200b of the second semiconductor substrate 200. The through insulation pattern 221 may be in contact with a part of the upper surface of the contact plug CP.

The through insulation pattern 221 may be formed of a low-k dielectric material having a dielectric constant lower than that of silicon oxide, for example. The through insulation pattern 221 may have a dielectric constant ranging from about 1.0 to about 3.0. The through insulation pattern 221 may be silicon oxide including carbon. The through insulation pattern 221 may be formed of, for example, a silicon oxide layer-based material doped with an impurity or an organic polymer having a low dielectric constant (Low-k). The impurity-doped oxide-layer-based material may be, for example, a fluorine-doped oxide (FSG), a carbon-doped oxide layer (e.g., SiC or SiCN), hydrogen silsesquioxane (HSQ; SiO:H), methyl silsesquoxane (MSQ; SiO; CH3), a-SiOC (SiOC:H), or the like. By forming the through insulation pattern 221 with a low dielectric material, parasitic capacitance between the floating diffusion regions FDa to FDd and a pixel transistor (e.g., a source follower transistor) may be reduced.

According to one or more embodiments, the pixel transistors may be provided on the first surface 200a of the second semiconductor substrate 200. In one or more embodiments, the source follower transistor SF (refer to FIGS. 2A and 2B) may be provided on the active portion ACT of the second semiconductor substrate 200.

For example, as a gate electrode of the source follower transistor, a pixel gate electrode PG may be disposed on the active portion ACT of the second semiconductor substrate 200, and source and drain regions may be provided in an active portion AT of the second semiconductor substrate 200 on opposite sides of the pixel gate electrode PG. Here, the source and drain regions may be impurity regions doped with impurities of the second conductivity type. A gate spacer formed of an insulating material may be provided on opposite sidewalls of the pixel gate electrode PG. The pixel gate electrode PG of the source follower transistor may be adjacent to the device isolation pattern 210 and the through insulation pattern 221.

According to one or more embodiments, the upper connection pattern ICP2 may be disposed on the first surface 200a of the second semiconductor substrate 200. The upper connection pattern ICP2 may extend continuously onto the upper surface of the pixel gate electrode PG on the upper surface of through plug TP. The upper connection pattern ICP2 may be in direct contact with the top surface of the through-plug TP, and may be in direct connection with a top surface of the pixel gate electrode PG.

The upper connection pattern ICP2 may have a substantially uniform thickness in the third direction D3, and may be in contact with the upper surface of the through insulation pattern 221 and the upper surface of the device isolation pattern 210. The thickness of the upper connection pattern ICP2 may be less than the thickness of the pixel gate electrode PG in the third direction D3.

The upper connection pattern ICP2 may be formed of a conductive material. The upper connection pattern ICP2 may formed of single-crystalline silicon or polysilicon doped with a dopant of the second conductivity type. In addition, the upper connection pattern ICP2 may include a metal material such as, for example, tungsten, titanium, tantalum, cobalt, or the like.

The upper connection pattern ICP2 may connect the through plug TP and the pixel gate electrode PG of the source follower transistor. The upper connection pattern ICP2 may be in contact with a top surface of the pixel gate electrode PG and a top surface of the through plug TP.

By connecting the pixel transistor and the floating diffusion regions through the upper connection pattern ICP2, capacitance may be reduced by wirings provided in a second interlayer insulating layer 250. Therefore, the conversion gain of the unit pixel may be increased, thereby to realize an image sensor having a clear image.

The second interlayer insulating layer 250 may cover the pixel transistors on the first surface 200a of the second semiconductor substrate 200. The second interlayer insulating layer 250 may include a plurality of insulating layers stacked, and the second interlayer insulating layer 250 may include, for example, silicon oxide, silicon nitride, and/or silicon oxynitride.

A light transmissive layer 30 may be disposed on the second surface 100b of the first semiconductor substrate 100. The light transmissive layer 30 may include a planarized insulating layer 510, a grid 520, color filters 530, and micro lenses 540. The light transmissive layer 30 may concentrate and filter externally incident light and provide the incident light to the photoelectric conversion circuit layer 10.

The planarized insulating layer 510 may cover and/or be provided on the second surface 100b of the first semiconductor substrate 100. The planarized insulating layer 510 may be formed of a transparent insulating material, and may include a plurality of layers. The planarized insulating layer 510 may be formed of an insulating material having a refractive index different from a refractive index of the first semiconductor substrate 100. The planarized insulating layer 510 may include, for example, a metal oxide and/or a silicon oxide.

The grid 520 may be disposed on the planarized insulating layer 510. The grid 520 may have a grating shape when viewed in a top plan view in the vertical direction (third direction D3), similar to the isolation structure PIS. When viewed in a top plan view, the grid 520 may overlap the isolation structure PIS in the vertical direction (third direction D3). For example, the grid 520 may include first portions extending in the first direction D1 and second portions extending in the second direction D2 across the first portions. The width of the grid 520 may be substantially equal to or less than the minimum width of the isolation structure PIS in the first direction D1 and/or second direction D2.

The grid 520 may include an optical blocking pattern and/or a low refractive pattern. The optical blocking pattern may include, for example, a metal material such as titanium, tantalum, or tungsten. The low refractive pattern may be formed of a material having a refractive index that is lower than a refractive index the optical blocking pattern. The low refractive pattern may be formed of an organic material and may have a refractive index of about 1.1 to 1.3. For example, the grid 520 may be a polymer layer in which silica nano-particles are included.

The color filters 530 may be formed to correspond to each of the pixel regions PR. The color filters 530 may fill a space defined by the grid 520. The color filters 530 may include red, green, or blue color filters, or magenta, cyan, or yellow color filters, depending on a unit pixel. In one or more embodiments, at least one of the color filters 530 may include a white color filter or an infrared filter.

The micro lenses 540 may be disposed on color filters 530. The micro lenses 540 may have a convex shape and a certain radius of curvature. The micro lenses 540 may be formed of a light transmissive resin. The micro lenses 540 may be disposed on the color filters 530 corresponding to each of the pixel regions PR. In one or more embodiments, at least one of the micro lenses 540 may be commonly disposed on at least two pixel regions PR.

For concise description, the same technical features as the image sensor described with reference to FIGS. 3, 4 and 5, may be omitted from the following description and different technical features will be described below.

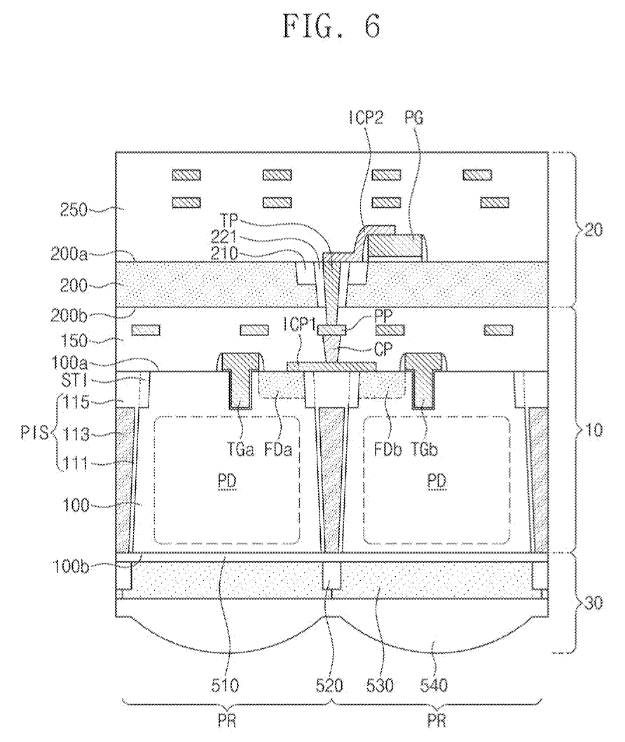

FIGS. 6, 7, 8 and 9 are cross-sectional views of an image sensor, corresponding to FIG. 4, according to one or more embodiments.

Referring to FIG. 6, a contact plug CP may be connected to the lower connection pattern ICP1 in the first interlayer insulating layer 150. A conductive pad PP may be disposed on a top surface of the contact plug CP, and a through plug TP may penetrate through the second semiconductor substrate 200 and a part of the first interlayer insulating layer 150 to be connected to the conductive pad PP. For example, a bottom surface of the through plug TP may be located at a lower level than the second surface 200b of the second semiconductor substrate 200 in the third direction D3.

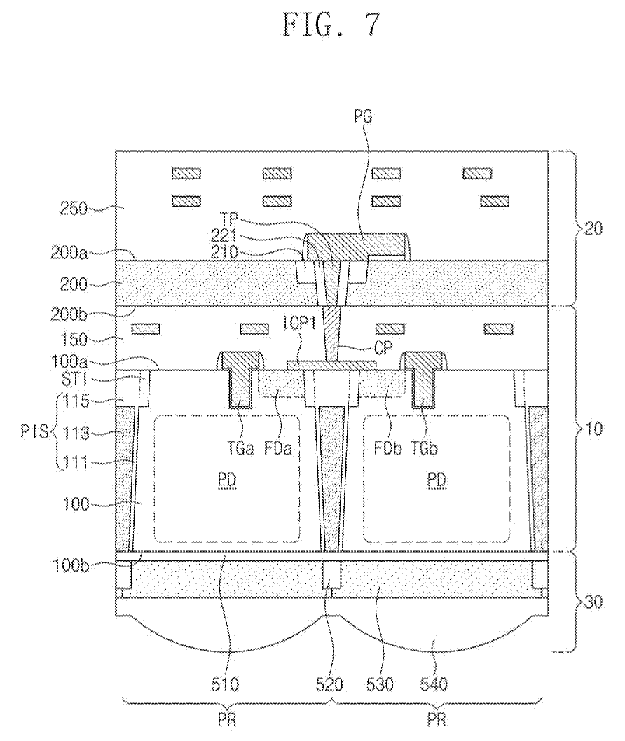

Referring to FIG. 7, as described above, the upper connection pattern may be omitted, and a portion of the pixel gate electrode PG may be in direct contact with the through plug TP on the first surface 200a of the second semiconductor substrate 200.

For example, a portion of the pixel gate electrode PG may overlap the through plug TP and the through insulation pattern 221, and a gate insulating layer may be interposed between the first surface 200a of the second semiconductor substrate and the lower surface of the pixel gate electrode PG. A portion of the pixel gate electrode PG may also be in direct contact with the device isolation pattern 210 and the through insulation pattern 221.

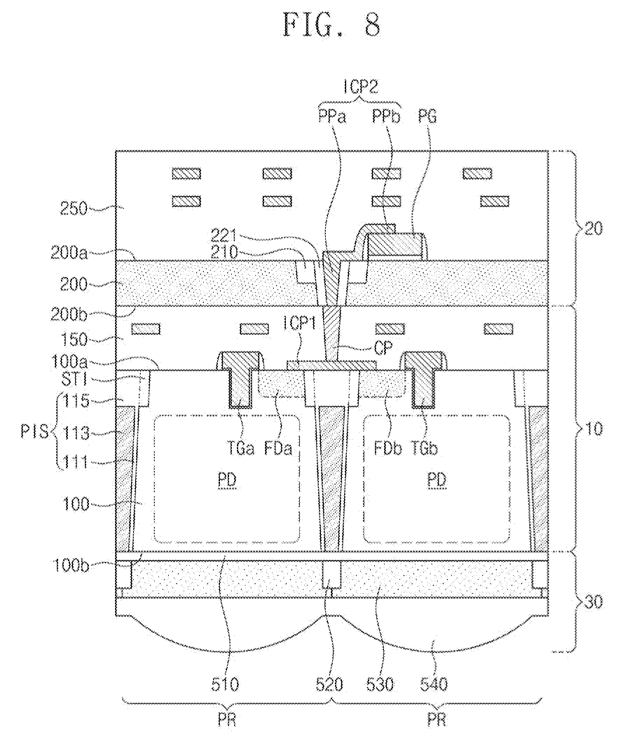

Referring to FIG. 8, the upper connection pattern ICP2 may extend continuously from the upper surface of the pixel gate electrode PG to the upper surface of a contact plug CP.

For example, the upper connection pattern ICP2 may include a first portion PPa vertically penetrating the second semiconductor substrate 200 and a second portion PPb disposed on the first surface 200a of the second semiconductor substrate 200. The through insulation pattern 221 penetrating the second semiconductor substrate 200 may surround and/or be adjacent to the first portion PPa of the upper connection pattern ICP2.

The upper connection pattern ICP2 may be in direct contact with the top surface of the contact plug CP, and may be in direct connection with the top surface the pixel gate electrode PG.

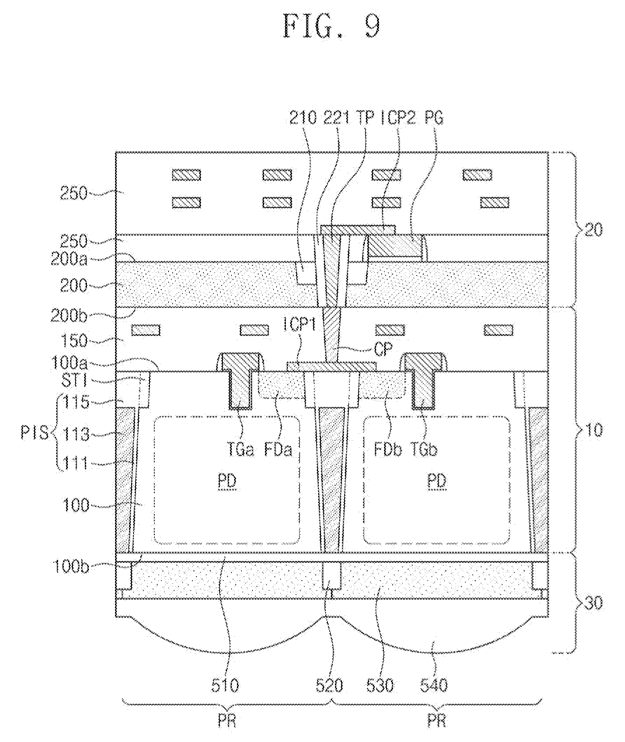

Referring to FIG. 9, the through plug TP and the through insulation pattern 221 may penetrate a part of the second interlayer insulating layer 250 provided on the first surface 200a of the second semiconductor substrate 200.

For example, the top surface of the through plug TP may be located at a different level from the first surface 200a of the second semiconductor substrate 200 in the third direction D3. In one or more embodiments, the top surface of the through plug TP may be located at a higher level than the top surface of through plug TP in the third direction D3. The top surface of the through plug TP may be located at substantially the same level as the top surface of the pixel gate electrode PG in the third direction D3.

The upper connection pattern ICP2 may have a uniform thickness, and may be in direct contact with the top surface of the through plug TP and the top surface of the pixel gate electrode PG.

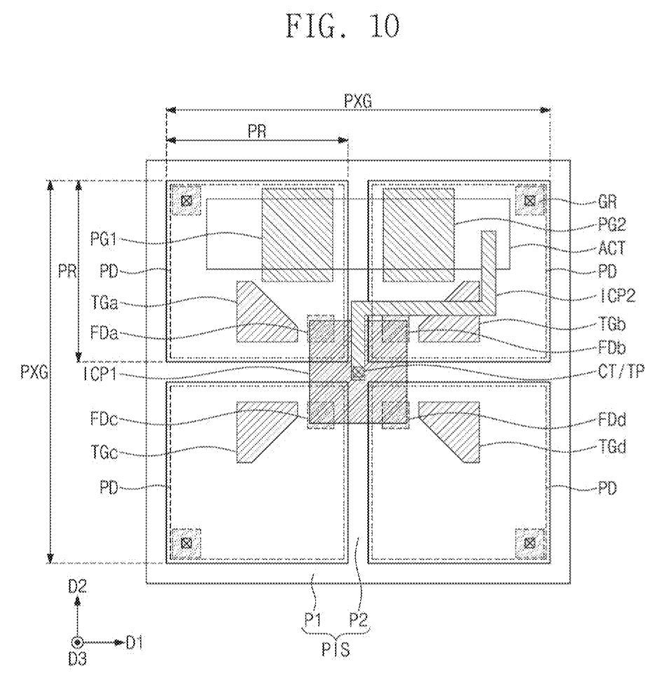

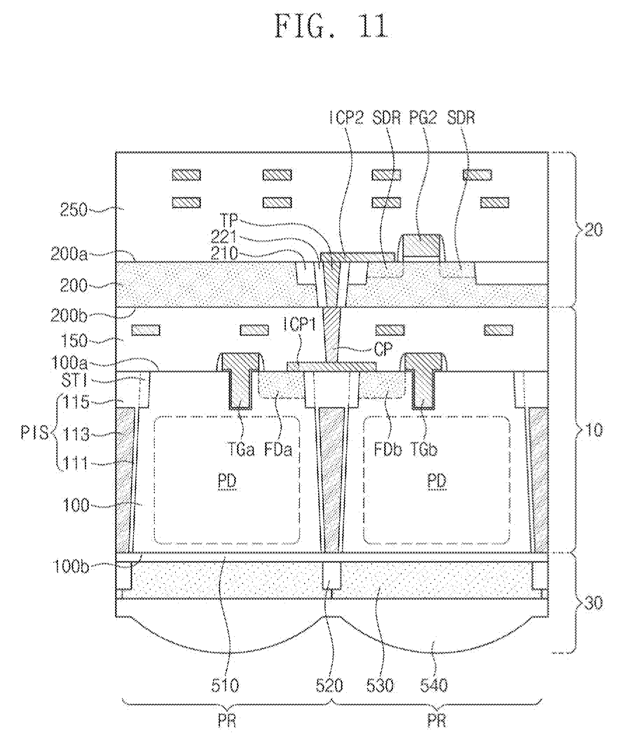

FIG. 10 is a schematic top plan view of an image sensor according to one or more embodiments. FIG. 11 is a cross-sectional view schematically illustrating the image sensor of FIG. 10 taken along line I-I’ shown in FIG. 10.

Referring to FIGS. 10 and 11, the image sensor may include a photoelectric conversion circuit layer 10, a pixel circuit layer 20, and a light transmissive layer 30.

The photoelectric conversion circuit layer 10 may include a first semiconductor substrate 100, an isolation structure PIS, a photoelectric conversion region PD, transfer gate electrodes TGa, TGb, TGc, and TGd, floating diffusion regions FDa, FDb, FDc, and FDd, a lower connection pattern ICP1, and a first interlayer insulating layer 150.

The pixel circuit layer 20 may include a second semiconductor substrate 200, a through plug TP, a through insulation pattern 221, and pixel transistors. As an example, a reset transistor RX (refer to FIGS. 2A and FIG. 2B) and a selection transistor SEL (refer to FIGS. 2A and 2B) may be provided on the first surface 200a of the second semiconductor substrate 200.

For example, the device isolation pattern 210 defining the active portion ACT may be provided in the second semiconductor substrate 200, and the first and second pixel gate electrodes PG1 and PG2 may be disposed on the active portion ACT spaced apart from each other.

Source and drain regions SDR may be provided in the active portion ACT of the second semiconductor substrate 200 on opposite sides of the first and second pixel gate electrodes PG1 and PG2. Here, the source and drain regions SDR may be an impurity region doped with impurities of the second conductivity type.

In one or more embodiments, the upper connection pattern ICP2 may extend to the top surface of one of the source and drain regions SDR on the top surface of the through plug TP. For example, the upper connection pattern ICP2 may directly connect the through plug TP and one of the source and drain regions SDR. For example, the upper connection pattern ICP2 may be in direct contact with the top surface of the through plug TP and the top surface of one of the source and drain regions SDR.

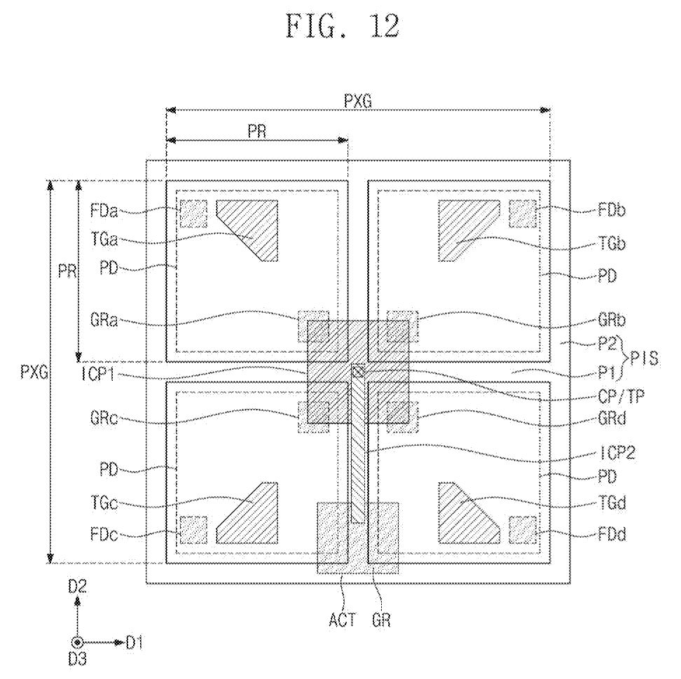

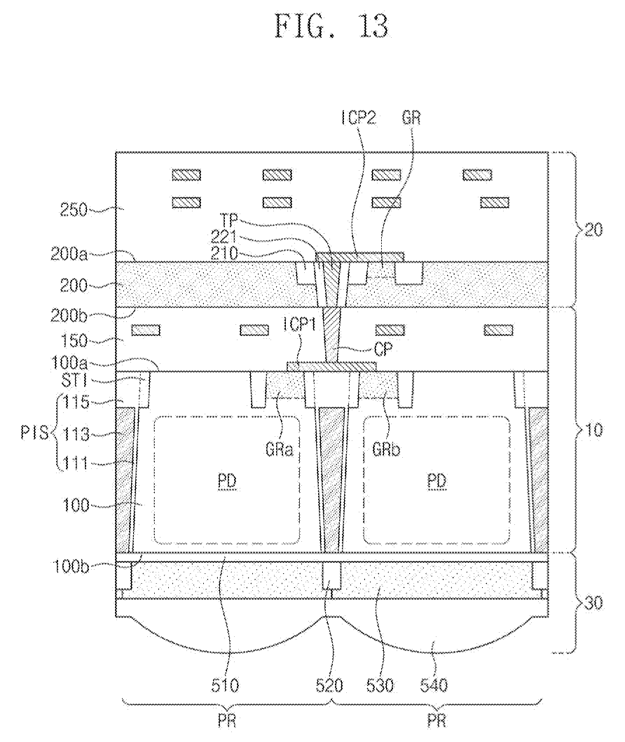

FIG. 12 is a schematic top plan view of an image sensor according to one or more embodiments. FIG. 13 is a cross-sectional view schematically illustrating the image sensor of FIG. 12 taken along line I-I’ shown in FIG. 12.

Referring to FIGS. 12 and 13, in each of the pixel regions PR, a ground impurity region GR may be provided in the first semiconductor substrate 100 to be spaced apart from the transfer gate electrodes TGa, TGb, TGc, and TGd. The ground impurity region GR may be formed by doping an impurity of the same first conductivity type as a conductivity type of the first semiconductor substrate 100. For example, the ground impurity region GR may be a p-type impurity region. A ground voltage may be applied to the first semiconductor substrate 100 through the ground impurity region GR. The ground impurity regions GR of the pixel regions PR may be disposed adjacent to each other.

The lower connection pattern ICP1 may be commonly connected to the ground impurity regions GR adjacent to each other. The lower connection pattern ICP1 may be in direct contact with the ground impurity regions GR.

A contact plug CP may penetrate through the first interlayer insulating layer 150 and be connected to the lower connection pattern ICP1.

The device isolation pattern 210 defining an active portion ACT may be disposed in the second semiconductor substrate 200. As an example, the ground impurity region GR doped with an impurity of the first conductivity type may be provided in the active portion ACT of the second semiconductor substrate 200.

A through plug TP may penetrate the second semiconductor substrate 200 and be connected with the contact plug CP, and the upper connection pattern ICP2 may extend on the upper surface of the through plug TP onto the upper surface of the ground impurity region GR in the second semiconductor substrate 20. The upper connection pattern ICP2 may be in direct contact with the top surface of the through plug TP and the top surface of the ground impurity region GR.

According to one or more embodiments, the ground impurity region GR in the second semiconductor substrate 200 may be electrically connected with the ground impurity regions GR in the first semiconductor substrate 100 through the upper connection pattern ICP2, the through plug TP, the contact plug CP, and the lower connection pattern ICP1.

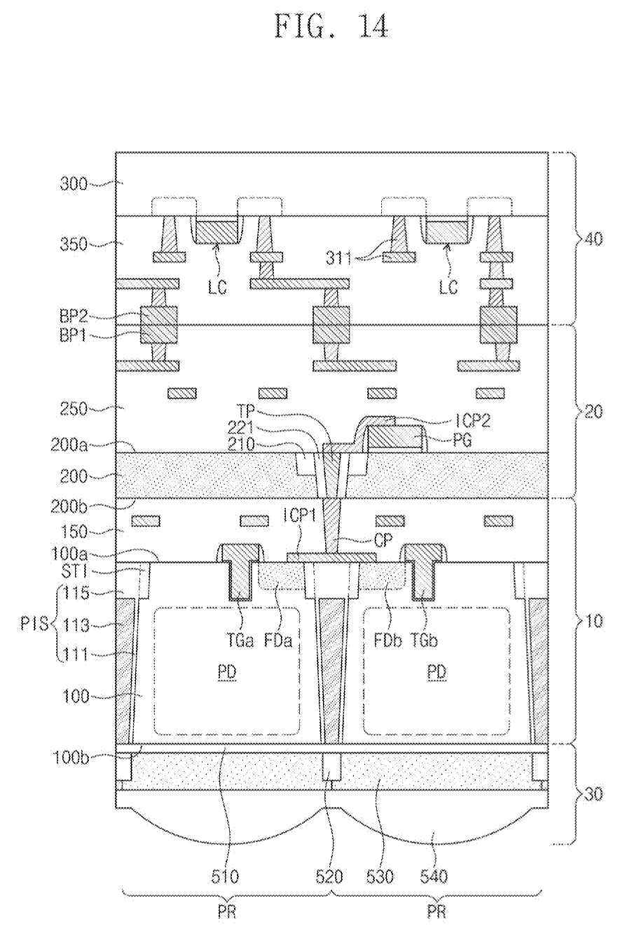

FIG. 14 is a schematic cross-sectional view of an image sensor according to one or more embodiments.

Referring to FIG. 14, an image sensor according to one or more embodiments may include a photoelectric conversion circuit layer 10, a pixel circuit layer 20, a light transmissive layer 30, and a logic circuit layer 40.

The photoelectric conversion circuit layer 10, the pixel circuit layer 20, and the light transmissive layer 30 may include substantially the same technical features as the embodiments described with reference to FIGS. 3 and 4 above. The pixel circuit layer 20 may further include first bonding pads BP1 provided in the uppermost metal layer in addition to the configuration of the above embodiments. The first bonding pads BP1 may be disposed in the uppermost layer of the first interlayer insulating layer 150. The first bonding pads BP1 may include, for example, at least one of tungsten (W), aluminum (Al), copper (Cu), tungsten nitride (WN), tantalum nitride (TaN), and titanium nitride (TiN).

The top surfaces of the first bonding pads BP1 may be substantially coplanar with the top surface of the first interlayer insulating layer 150. The first bonding pads BP1 may be electrically connected with the pixel transistors through contact plugs and metal wirings.

The logic circuit layer 40 may be bonded with the pixel circuit layer 20. The logic circuit layer 40 may include logic circuits 2, 3, 4, 5, 6, 7, and 8 (refer to FIG. 1), a power supply circuit, an input/output interface, an image signal processor, and/or the like. For example, the logic circuit layer 40 may include components other than the active pixel sensor array 1 in the image sensor of FIG. 1.

For example, the logic circuit layer 40 may include a third semiconductor substrate 300, logic circuits LC, a logic interlayer insulating layer 350 covering and/or provided on the logic circuits LC and logic wirings 311 connected with the logic circuits LC. The logic interlayer insulating layer 350 may include a plurality of insulating layers stacked.

The second bonding pads BP2 may be provided in the uppermost layer of the logic interlayer insulating layer 350, and upper surfaces of the second bonding pads BP2 may be substantially coplanar with the uppermost surface of the logic interlayer insulating layer 350. The second bonding pads BP1 may include, for example, at least one of tungsten (W), aluminum (Al), copper (Cu), tungsten nitride (WN), tantalum nitride (TaN), and titanium nitride (TiN).

The first bonding pads BP1 and the second bonding pads BP2 may be directly and electrically connected to each other in a hybrid bonding manner. For example, the top surface of the logic interlayer insulating layer 350 may be bonded with the second interlayer insulating layer 250 of the pixel circuit layer 20. The second bonding pads BP1 may be bonded with the first bonding pads BP2 of the pixel circuit layer 20.

By directly bonding the first and second bonding pads BP1 and BP2 to each other, the pixel circuit layer 20 may be electrically connected to the logic circuit layer 40.

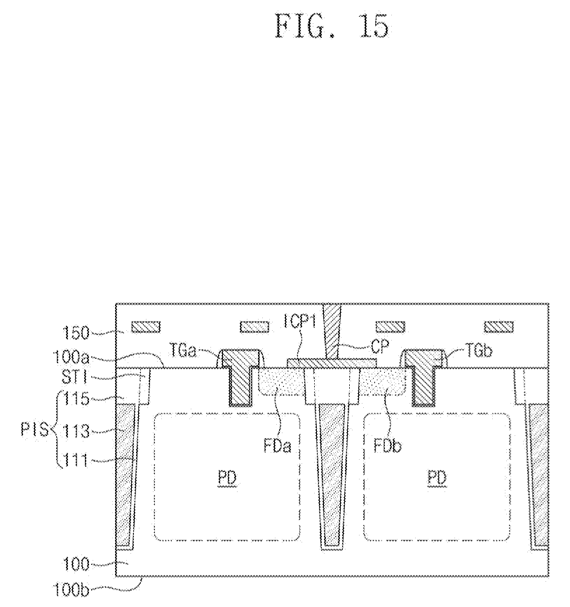

FIGS. 15 to 19 are cross-sectional views for illustrating a method of manufacturing an image sensor according to one or more embodiments.

Referring to FIG. 15, the first semiconductor substrate 100 of a first conductivity type (e.g., p-type) may be provided. For example, the first semiconductor substrate 100 may include an epitaxial layer. The first semiconductor substrate 100 may have the first surface 100a and the second surface 100b opposite to each other.

As another example, the first semiconductor substrate 100 may be a bulk silicon substrate including wells of a first conductivity type. In one or more embodiments, the first semiconductor substrate 100 may be, for example, a silicon-on-insulator (SOI) substrate, a germanium (Ge) substrate, a germanium-on-insulator (GOI) substrate, or a silicon-germanium (Si-Ge) substrate.

The shallow trench isolation pattern STI may define active portions in each of the pixel regions PR of the first semiconductor substrate 100 and may be adjacent to the first surface 100a of the first semiconductor substrate 100. Forming the shallow trench isolation pattern STI may include patterning the first surface 100a of the first semiconductor substrate 100 to form a shallow first trench, forming a liner insulating layer conformally covering and/or being provided on an inner wall of the first trench, and forming an insulating layer filling the first trench in which the liner insulating layer is formed. Forming the shallow trench isolation pattern STI may be formed before or after forming the photodiode PD regions.

The isolation structure PIS defining pixel regions PR may be formed in the first semiconductor substrate 100. Forming the isolation structure PIS may include patterning the first surface 100a of the first semiconductor substrate 100 to form a second trench, forming a liner insulating layer conformally covering and/or being provided on an inner wall of the second trench, depositing a semiconductor layer to fill the second trench in which the liner insulating layer is formed, and planarizing the liner insulating layer and the semiconductor layer to expose the first surface 100a of the first semiconductor substrate 100 such that the liner insulation pattern 111, the gap-fill pattern 113, and the capping insulation pattern 115 are formed in the second trench.

The liner insulation pattern 111 and the capping insulation pattern 115 may include, for example, silicon oxide, silicon nitride, and/or silicon oxynitride. The gap-fill pattern 113 may include a doped polysilicon layer and/or an undoped polysilicon layer.

Thereafter, the photodiode PD regions may be respectively provided in the first semiconductor substrate 100 in the pixel regions PR.

The photodiode PD regions in the pixel regions PR may be formed by doping an impurity of a second conductivity type (e.g., n-type) different from the first conductivity type in the first semiconductor substrate 100. The photodiode PD regions may be spaced apart from the first surface 100a and the second surface 100b of the first semiconductor substrate 100. The photodiode PD regions may be formed before or after forming the isolation structure PIS.

Thereafter, transfer gate electrodes TGa to TGd may be formed on the first semiconductor substrate 100 in the pixel regions PR. Forming the transfer gate electrodes TGa to TGd may include patterning the first surface 100a of the first semiconductor substrate 100 to form a gate recess region in each of the pixel regions PR, forming a gate insulating layer conformally covering and/or being provided on an inner wall of the gate recess region, and forming a gate conductive layer filling the gate recess region and patterning the gate conductive layer. In some embodiments, each of the transfer gate electrodes TGa to TGd may include two vertical portions disposed in the first semiconductor substrate 100.

The gate insulating layer may include, for example, a silicon oxide layer, a silicon oxynitride layer, or a silicon nitride layer. The gate insulating layer may be formed by performing a deposition process so as to conformally cover and/or be provided on an inner wall of a vertical trench VT.

The transfer gate electrodes TGa to TGd may be formed by forming a gate conductive layer filling a vertical trench in which the gate insulating layer is formed and then patterning the gate conductive layer. The gate conductive layer may include a doped polysilicon layer, a metal silicide layer, a conductive metal nitride layer, or a metal layer.

After forming the transfer gate electrodes TGa to TGd, floating diffusion regions FDa to FDd may be formed in the first semiconductor substrate 100 on one sides of the transfer gate electrodes TGa to TGd. The floating diffusion regions FDa to FDd may be formed by ion implanting impurities of the second conductivity type using an ion implantation mask.

Thereafter, a lower connection pattern ICP1 connecting the floating diffusion regions FDa to FDd adjacent to each other may be formed on the first surface 100a of the first semiconductor substrate 100.

Forming the lower connection pattern ICP1 may include depositing a spacer insulating layer covering and/or being provided on the first surface 100a of the first semiconductor substrate 100 and the sidewalls and top surfaces of the transfer gate electrodes TGa to TGd , patterning the spacer insulating layer to expose the top surfaces of the floating diffusion regions FDa to FDd, depositing a conductive layer on the floating diffusion regions FDa to FDd and the spacer insulating layer, patterning the conductive layer, and anisotropically etching the spacer insulating layer.

A first interlayer insulating layer 150 covering the transfer gate electrodes TGa to TGd and the lower connection pattern ICP1 may be formed on the first surface 100a of the first semiconductor substrate 100.

The first interlayer insulating layer 150 may include a plurality of insulating layers stacked. The first interlayer insulating layer 150 may include, for example, at least one of a silicon oxide layer, a silicon oxynitride layer, and a silicon nitride layer. The first interlayer insulating layer 150 may be formed by using at least one of physical vapor deposition (PVD) process, chemical vapor deposition (CVD) process, or atomic layer deposition (ALD) process.

Thereafter, a contact plug CP which penetrates through the first semiconductor substrate 100 and is connected to the lower connection pattern ICP1 may be formed. Forming the contact plug CP may include patterning the first interlayer insulating layer 150 to form a contact hole exposing a part of the lower connection pattern ICP1, depositing a conductive layer filling the contact hole, and planarizing the conductive layer to expose t a top surface of the first interlayer insulating layer 150.

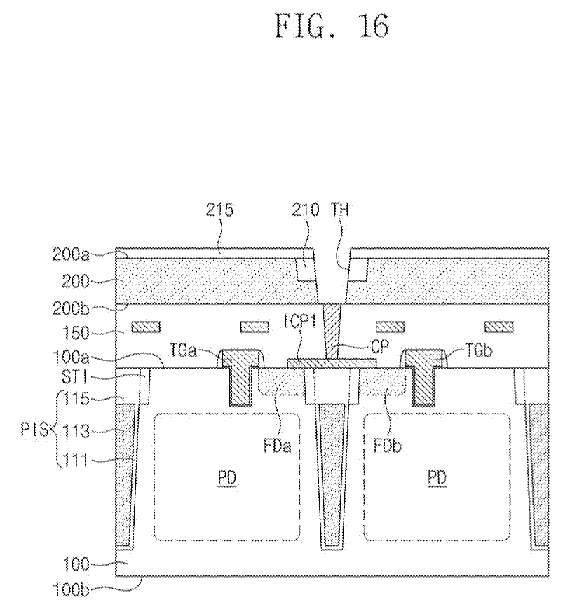

Referring to FIG. 16, the second semiconductor substrate 200 may be bonded on the first interlayer insulating layer 150 of the first semiconductor substrate 100. The second semiconductor substrate 200 may have the first surface 200a and the second surface 200b opposite to each other, and the second surface 200b may be in contact with the upper surface of the first interlayer insulating layer 150. The second semiconductor substrate 200 may be a bulk silicon substrate or a substrate in which an epitaxial layer is formed on a bulk silicon substrate.

A device isolation pattern 210 defining an active portion ACT may be formed in portions of the second semiconductor substrate 200. The device isolation pattern 210 may include, for example, at least one of a silicon oxide layer, a silicon oxynitride layer, and/or a silicon nitride layer.

Forming the device isolation pattern 210 may include patterning the first surface 200a of the second semiconductor substrate 200 to form a trench defining the active portion ACT, depositing an insulating layer filling the trench, and planarizing the insulating layer to expose the first surface 200a of the second semiconductor substrate 200. Thus, the upper surface of the device isolation pattern 210 may be substantially coplanar with the upper surface of the second semiconductor substrate 200.

The active portion ACT corresponds to portions of the second semiconductor substrate 200 and may be single-crystalline silicon. The active portion ACT may overlap a portion of the photodiode PD regions and a portion of the isolation structure PIS when viewed in a top plan view. The active portion ACT may have, for example, a rectangular or bar shape.

After forming the active portion ACT, a buffer mask pattern 215 may be formed on the first surface 200a of the second semiconductor substrate 200.

Next, using the buffer mask pattern 215 as an etching mask, a through hole TH may be formed by anisotropically etching the second semiconductor substrate 200. The through hole TH may penetrate the second semiconductor substrate 200 to expose the contact plug CP.

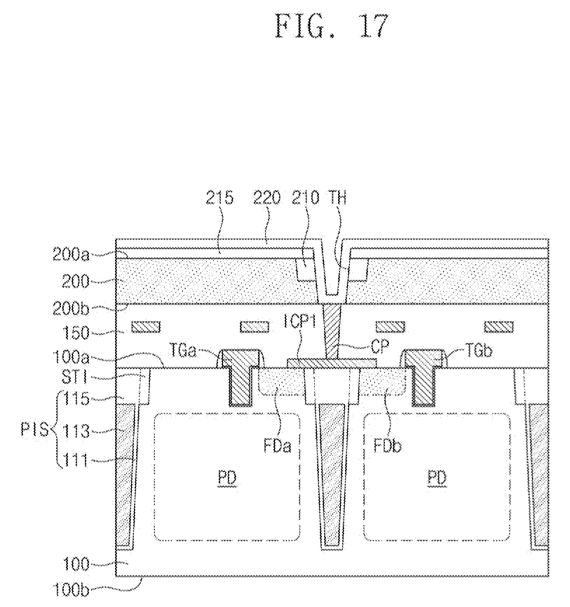

Referring to FIG. 17, a spacer insulating layer 220 covers the inner wall of the through hole TH with a uniform thickness in the third direction D3, and may be deposited on the first surface 200a of the second semiconductor substrate 200.

The deposition thickness of the spacer insulating layer 220 may be less than about 1⁄2 of the diameter of the through hole TH. The spacer insulating layer 220 may define a gap region in the through hole TH.

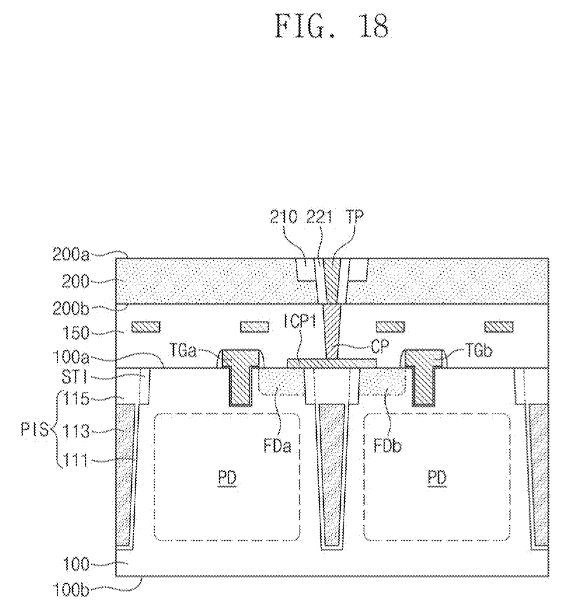

Referring to FIG. 18, a through insulation pattern 221 may be formed in the through hole TH by performing an etch-back process on the spacer insulating layer 220. By forming the through insulation pattern 221, the first surface 200a of the second semiconductor substrate 200 and the upper surface of the contact plug CP may be exposed.

In one or more embodiments, before the through insulation pattern 221 is formed, a doped region may be formed in the contact plug CP by doping an impurity in the contact plug CP exposed in the through hole TH.

Subsequently, after the conductive layer filling the through hole TH in which the through insulation pattern 221 is formed is deposited, a planarization process is performed so that the first surface 200a of the second semiconductor substrate 200 is exposed, whereby the through plug TP may be formed.

The through plug TP may include, for example, a polysilicon layer doped with impurities, a metal, a conductive metal nitride, a conductive metal silicide, a conductive metal oxide, or a combination thereof.

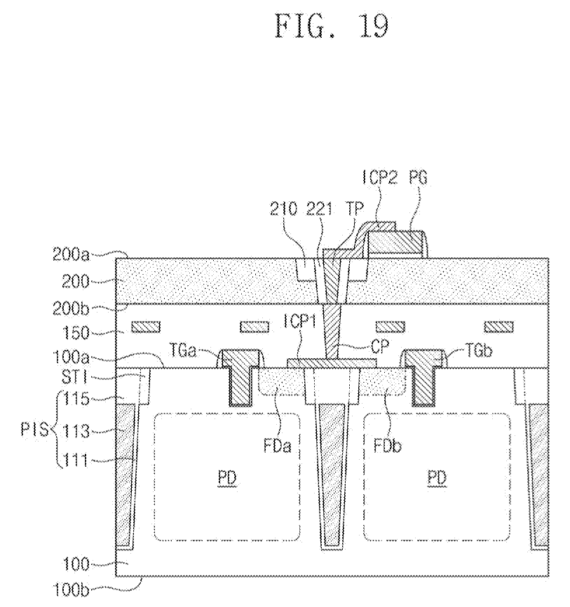

Referring to FIG. 19, a pixel gate electrode PG may be formed on the active portion ACT with a gate insulating layer interposed therebetween. After forming the pixel gate electrode PG, source/drain regions SDR may be formed in the active portion ACT on opposite sides of each pixel gate electrode PG. The pixel gate electrode PG may be disposed adjacent to the through insulation pattern 221.

The pixel gate electrode PG may include, for example, a high-melting-point metal layer such as cobalt, titanium, nickel, tungsten, and molybdenum and/or a metal nitride layer such as a titanium nitride layer (TiN), a titanium silicon nitride layer (TiSiN), a titanium aluminum nitride layer (TiAlN), a tantalum nitride layer (TaN), a tantalum silicon nitride (TaSiN), a tantalum aluminum nitride layer (TaAlN), and a tungsten nitride layer.

Subsequently, after forming the gate spacers on opposite sidewalls of the pixel gate electrode PG, an upper connection pattern ICP2 connecting the through plug TP and the pixel gate electrode PG may be formed. The gate spacers may be formed of an insulating material, and the upper connection pattern ICP2 may be formed of a conductive material.

The upper connection pattern ICP2 may be formed by depositing a conductive layer on the first surface 200a of the second semiconductor substrate 200 and the pixel gate electrode PG, and then patterning the conductive layer.

In one or more embodiments, before forming the upper connection pattern ICP2, the upper surface of the through plug TP may be doped with impurities to form a doped region in the upper portion of the through plugs TP.

Thereafter, a thinning process of removing a portion of the first semiconductor substrate 100 may be performed to reduce the vertical thickness of the first semiconductor substrate 100. The thinning process includes grinding or polishing and anisotropic and isotropic etching the second surface 100b of the first semiconductor substrate 100. In order to thin the first semiconductor substrate 100, the top and bottom of the first semiconductor substrate may be inverted. The bulk silicon substrate of the first semiconductor substrate 100 may be removed by a grinding or polishing process, and the epitaxial layer may be exposed. An anisotropic or isotropic etch process may then be performed to remove surface defects present on the exposed surface of the epitaxial layer.

The gap-fill pattern 113 of the isolation structure PIS may be exposed at the second surface 100b of the first semiconductor substrate 100 by a thinning process on the first semiconductor substrate 100. The surface of the gap-fill pattern 113 and the surface of the liner insulation pattern 111 may be located at substantially the same level as the second surface 100b of the first semiconductor substrate 100.

Thereafter, as shown in FIG. 4, a planarized insulating layer 510 may be formed on the second surface 100b of the first semiconductor substrate 100. The planarized insulating layer 510 may cover and/or be provided on the second surface 100b of the first semiconductor substrate 100. The planarized insulating layer 510 may be formed by depositing a metal oxide such as aluminum oxide and/or hafnium oxide.

Next, a grid 520, color filters 530, and micro lenses 540 may be formed on the planarized insulating layer 510.

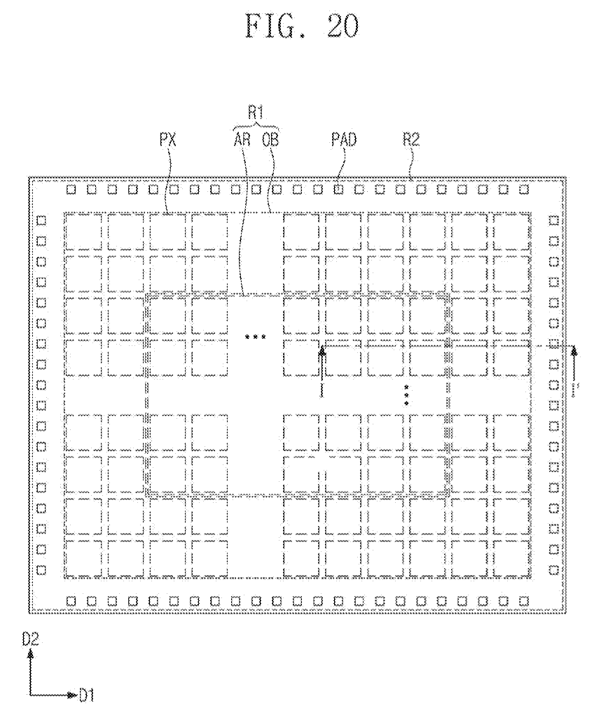

FIG. 20 is a schematic top view of an image sensor according to one or more embodiments. FIGS. 21 and 22 are cross-sectional views of an image sensor according to one or more embodiments, illustrating a cross-section along line I-I′ of FIG. 20.

Referring to FIGS. 20 and 21, the image sensor may include a pixel array region R1 and a pad region R2. The pixel array region R1 may include a plurality of unit pixels PX two-dimensionally arranged along a first direction D1 and a second direction D2 intersecting each other. Each of the unit pixels PX may include a photodiode and readout elements. An electrical signal generated by incident light may be output from each of the unit pixels PX of the pixel array region R1.

The image sensor may be provided to have the same features as the light-receiving region AR of the image sensor described above. For example, the image sensor may include the photoelectric conversion circuit layer 10, the pixel circuit layer 20, the light transmissive layer 30, and the logic circuit layer 40, as described above. The pixel circuit layer 20 may be disposed between the photoelectric conversion circuit layer 10 and the light transmissive layer 30, and the pixel circuit layer 20 may be adjacent to the logic circuit layer 40.

The isolation structure PIS in the first semiconductor substrate 100 may define pixel regions in the light-receiving region AR and a light-blocking region OB. A portion of the isolation structure PIS, e.g., the gap-fill pattern 113, may be electrically connected with a backside contact plug 521 in the light blocking region OB.

The planarized insulating layer 510 of the light transmissive layer 30 may extend from the light receiving region AR to the light-blocking region OB and the pad region R2.

In the light-blocking region OB, a light-blocking pattern OBP may be disposed on the planarized insulating layer 510. The light-blocking pattern OBP may block light from entering the photodiode PD regions provided in the light-blocking region OB.

The light transmissive layer 30 may include the light-blocking pattern OBP, a filtering layer 535, and an organic layer 545 in the light shielding region OB. In one or more embodiments, the isolation structure PIS may extend continuously from the light receiving region AR to the light blocking region OB.

When viewed in a top plan view, the light-blocking region OB may surround and/or be adjacent to the light-receiving region AR. For example, the light-blocking region OB may surround the light-receiving region AR in four different directions (e.g., up, down, left, and rights directions), when viewed in a top plan view. In one or more embodiments, reference pixels on which light is not incident may be provided in the light shielding region OB, and a magnitude of an electric signal sensed in the unit pixels PX may be calculated or obtained by comparing an amount of charges sensed in the unit pixels PX of the light-receiving region AR with a reference amount of charges generated in the reference pixels.

The isolation structure PIS may define pixel regions in the light-receiving region AR and the light-blocking region OB, and the isolation structure PIS may have substantially the same structure in the light-receiving region AR and in the light-blocking region OB.

In the light blocking region OB, the isolation structure PIS may be disposed in the first semiconductor substrate 100. The gap-fill pattern 113 in the isolation structure PIS may be electrically connected with the backside contact plug 521 in the light blocking region OB. A predetermined bias may be applied to the gap-fill pattern 113 via the backside contact plug 521. The backside contact plug 521 may have a width that is greater than a width of the isolation structure PIS in the first direction D1 and/or the second direction D2. The backside contact plug 521 may include a metal and/or a metal nitride. For example, the backside contact plug 521 may include titanium and/or titanium nitride.

In the light blocking region OB, the backside contact plug 521 may be provided on the second surface 100b of the first semiconductor substrate 100. A contact trench may be formed in the second surface 100b of the first semiconductor substrate 100, and the backside contact plug 521 may be provided in the contact trench.

A contact pattern 522 may be buried in the contact hole in which the backside contact plug 521 is formed. The contact pattern 522 may include a material that is different from a material of the backside contact plug 521. For example, the contact pattern 522 may include aluminum (Al).

The contact pattern 522 and the backside contact plug 521 may be electrically connected with the gap-fill pattern 113 of the isolation structure PIS. A negative bias may be applied to the gap-fill pattern 113 of the isolation structure PIS through the contact pattern CT, and the negative bias may be transferred from the light-blocking region OB to the light-receiving region AR. Accordingly, the dark current generated at the interface between the isolation structure PIS and the first semiconductor substrate 100 may be reduced.

The light-blocking pattern OBP may block light from being incident on the photodiode PD regions, in the light-blocking region OB. The photodiode PD regions may output a noise signal without outputting a photoelectric signal in reference pixel regions of the light shielding region OB. The noise signal may be generated due to electrons generated by dark current or heat generation. The light-blocking pattern OBP may include, for example, a metal such as tungsten, copper, aluminum, or an alloy thereof.

The filtering layer 535 may cover the light-blocking pattern OBP in the light-blocking region OB. The filtering layer 535 may block light of a wavelength different from the color filters 530. For example, the filtering layer 535 may block infrared light. The filtering layer 535 may include a blue color filter, but embodiments are not limited to this example.

The organic layer 545 and a passivation layer may be provided on the filtering layer 535 in the light-blocking region OB and the pad region R2. The organic layer 545 may be formed of or include a material same as a material of the micro lenses 540.

The logic circuit layer 40 may be electrically connected with the photoelectric conversion circuit layer 10 through a first through conductive pattern 523 and a second through conductive pattern 525. The logic circuit layer 40 may include a power supply circuit, an input/output interface, an image signal processor, and the like. The logic circuit layer 40 may be electrically connected with the photoelectric conversion circuit layer 10 through the first through conductive pattern 523 and the second through conductive pattern 525.

For example, in the light-blocking region OB, the first through conductive pattern 523 may penetrate through the first semiconductor substrate 100 to be electrically connected with the conductive lines ML of the pixel circuit layer 20 and the wiring structure of the logic circuit layer 40. The first through conductive pattern 523 may have a first bottom surface and a second bottom surface located at different levels in the third direction D3. The first gap-fill pattern 524 may be provided inside the first through conductive pattern 523. The first gap-fill pattern 524 may include a low refractive index material and may have insulating properties.

In the pad region R2, a plurality of conductive pads PAD used for inputting and outputting control signals, a photoelectric signal, and the like may be disposed on the second surface 100b of the first semiconductor substrate 100. The pad region R2 may surround and/or be adjacent to the pixel array region R1, when viewed in a top plan view, so as to facilitate electrical connection with external elements. The conductive pads PAD may input and output electrical signals generated in the unit pixels PX to and from an external device.

In the pad region R2, the conductive pads PAD may be provided on the second surface 100b of the first semiconductor substrate 100. The conductive pads PAD may be buried in the first semiconductor substrate 100 and near the second surface 100b. In one or more embodimnts, the conductive pads PAD may be provided in pad trenches formed in the second surface 100b of the first semiconductor substrate 100, in the pad region R2. The conductive pads PAD may be formed of or include at least one of metallic materials (e.g., aluminum, copper, tungsten, titanium, tantalum, or alloys thereof). In a process of mounting an image sensor, bonding wires may be bonded to the conductive pads PAD. The conductive pads PAD may be electrically connected to an external device through the bonding wires.

In the pad region R2, the second through conductive pattern 525 may penetrate through the first semiconductor substrate 100 to be electrically connected with the logic wirings 311 of the logic circuit layer 40. The second through conductive pattern 525 may extend onto the second surface 100b of the first semiconductor substrate 100 to electrically connect with the conductive pads PAD. A portion of the second through conductive pattern 525 may cover and/or be provided on a bottom surface and a sidewall of the conductive pads PAD. A second gap-fill pattern 526 may be provided inside the second through conductive pattern 525. The second gap-fill pattern 526 may include a relatively low refractive index material and may have insulating properties. In the pad region R2, the isolation structure PIS may be provided around and/or adjacent to the second through conductive pattern 525.

In one or more embodiments, the pixel circuit layer 20 and the logic circuit layer 40 are described as being electrically connected to each other through the first and second through conductive patterns 523 and 525, but embodiments are not limited thereto.

According to the embodiment shown in FIG. 22, the first and second through conductive patterns 523 and 525 shown in FIG. 21 may be omitted, and the pixel circuit layer 20 and the logic circuit layer 40 may be electrically connected by directly bonding the bonding pads BP1 and BP2 provided as the uppermost metal layer of the pixel circuit layer 20 and the logic circuit layer 40 to each other.

For example, the pixel circuit layer 20 of the image sensor may include first bonding pads BP1 provided in the top metal layer, and the logic circuit layer 40 may include second bonding pads BP2, which are provided in the uppermost metal layer of the interconnection structure 1111. The first and second bonding pads BP1 and BP2 may be formed of or include at least one of, for example, tungsten (W), aluminum (Al), copper (Cu), tungsten nitride (WN), tantalum nitride (TaN), or titanium nitride (TiN).

The first bonding pads BP1 of the pixel circuit layer 20 and the second bonding pads BP2 of the logic circuit layer 40 may be electrically and directly connected to each other by a hybrid bonding method. The hybrid bonding structure may refer to bonding for fusing two components including homogeneous materials at an interface therebetween. For example, when the first and second bonding pads BP1 and BP2 are formed of copper (Cu), the first and second bonding pads BP1 and BP2 may be physically and electrically connected through copper (Cu)-copper (Cu) bonding. Furthermore, a surface of an insulating layer of the pixel circuit layer 20 and a surface of an insulating layer of the logic circuit layer 40 may be bonded through dielectric-dielectric bonding.

According to one or more embodiments, the floating diffusion region provided in the first semiconductor substrate and the pixel transistor provided in the second semiconductor substrate on the first semiconductor substrate may be connected to each other through a contact plug and a through plug. Accordingly, the through plug may be formed to be buried in the second semiconductor substrate, so that the size of the through plug may be reduced. Therefore, the size of the unit pixel of the image sensor may be further reduced.

In addition, by forming a connection conductive pattern that connects the floating diffusion region and the pixel transistor on the second semiconductor substrate, it may be possible to prevent an increase of capacitance and a delay of signals, which may occur when a metal layer is used for the connection, and to improve a conversion gain in a unit pixel. In addition, it may be possible to increase a degree of freedom of constructing an interconnection structure of the image sensor.

While embodiments have been described with reference to the figures, it will be understood by those of ordinary skill in the art that various changes in form and details may be made therein without departing from the spirit and scope as defined by the following claims and their equivalents and their equivalents.

What is claimed is:

1. An image sensor, comprising: a first semiconductor substrate; a second semiconductor substrate on the first semiconductor substrate; a floating diffusion region in the first semiconductor substrate; a contact plug between the first semiconductor substrate and the second semiconductor substrate, and connected with the floating diffusion region; a through plug penetrating through the second semiconductor substrate and connected with the contact plug; a pixel transistor on the second semiconductor substrate; and an upper connection pattern connecting the through plug with the pixel transistor on the second semiconductor substrate,wherein the upper connection pattern contacts a first surface of the through plug.

2. The image sensor of claim 1, further comprising a through insulation pattern penetrating the second semiconductor substrate and on a sidewall of the through plug.

3. The image sensor of claim 2, wherein the through insulation pattern comprises a low-k dielectric material having a dielectric constant lower than a dielectric constant of silicon oxide.

4. The image sensor of claim 2, wherein a portion of a first surface of the contact plug contacts the through insulation pattern.

5. The image sensor of claim 1, wherein the pixel transistor comprises a pixel gate electrode on an active portion in the second semiconductor substrate, and wherein the upper connection pattern contacts a first surface of the through plug and a first surface of the pixel gate electrode.

6. The image sensor of claim 1, wherein the pixel transistor comprises a pixel gate electrode on an active portion in the second semiconductor substrate and source/drain regions at opposite sides of the pixel gate electrode, and
wherein the upper connection pattern contacts the first surface of the through plug and a first surface of one of the source/drain regions.

7. The image sensor of claim 1, wherein the first surface of the through plug is coplanar with a first surface of the second semiconductor substrate, and wherein a second surface of the through plug is coplanar with a second surface of the second semiconductor substrate.

8. The image sensor of claim 1, wherein the contact plug comprises a doped polysilicon with dopants of a first conductivity type, and wherein the contact plug comprises a first doped region of the first conductivity type contacting a second surface of the through plug.

9. The image sensor of claim 1, wherein the through plug comprises a doped polysilicon with dopants of a first conductivity type, and wherein the through plug comprises a second doped region of the first conductivity type contacting the upper connection pattern.

10. The image sensor of claim 1, further comprising: an isolation structure in the first semiconductor substrate, the isolation structure defining a plurality of pixel regions; and a lower connection pattern contacting floating diffusion regions in at least two pixel regions of the plurality of pixel regions adjacent to each other.

11. The image sensor of claim 10, wherein the floating diffusion region comprises a low doped region and a high doped region in the low doped region, wherein a dopant concentration of the high doped region is higher than a dopant concentration of the low doped regions, and wherein the lower connection pattern contacts the high doped region of the floating diffusion region.

12. The image sensor of claim 10, wherein the lower connection pattern contacts a portion of a first surface of the isolation structure.

13. An image sensor, comprising: a first semiconductor substrate; a second semiconductor substrate on the first semiconductor substrate; a floating diffusion region in the first semiconductor substrate; a lower connection pattern on the first semiconductor substrate and in contact with the floating diffusion region; a contact plug between the first semiconductor substrate and the second semiconductor substrate, and connected with the lower connection pattern; a through plug penetrating the second semiconductor substrate and connected with the contact plug; a through insulation pattern penetrating the second semiconductor substrate and on a sidewall of the through plug; a source follower gate electrode on the second semiconductor substrate; and an upper connection pattern contacting a first surface of the through plug and a first surface of the source follower gate electrode.

14. The image sensor of claim 13, further comprising an isolation structure in the first semiconductor substrate and defining a plurality of pixel regions, wherein the floating diffusion region is in each of the plurality of pixel regions, and wherein the lower connection pattern contacts the floating diffusion regions in at least two pixel regions of the plurality of pixel regions adjacent to each other.

15. The image sensor of claim 13, wherein the through insulation pattern comprises a low-k dielectric material having a dielectric constant lower than a dielectric constant of silicon oxide.

16. The image sensor of claim 13, wherein the source follower gate electrode is adjacent to the through insulation pattern.

17. The image sensor of claim 13, wherein the contact plug and the through plug comprise a doped polysilicon layer with dopants of a first conductivity type, wherein the contact plug comprises a first doped region of the first conductivity type in contact with a second surface of the through plug, wherein the through plug comprises a second doped region of the first conductivity type in contact with the upper connection pattern, wherein a doping concentration of the first doped region and a doping concentration of the second doped region is greater than a doping concentration of the doped polysilicon layer.

18. An image sensor, comprising: a first semiconductor substrate; a second semiconductor substrate on the first semiconductor substrate; an isolation structure in the first semiconductor substrate and defining pixel regions; photodiode regions in the pixel regions in the first semiconductor substrate, respectively; floating diffusion regions in each of the pixel regions in the first semiconductor substrate, respectively; transfer gate electrodes respectively between the photodiode regions and the floating diffusion regions; a lower connection pattern contacting the floating diffusion regions in at least two pixel regions of the pixel regions adjacent to each other; a contact plug between the first semiconductor substrate and the second semiconductor substrate, and connected with the lower connection pattern; a through plug penetrating through the second semiconductor substrate and connected with the contact plug; a through insulation pattern penetrating the second semiconductor substrate and on a sidewall of the through plug; a pixel transistor on the second semiconductor substrate; and an upper connection pattern connecting the through plug and the pixel transistor, wherein the upper connection pattern is in contact with a first surface of the through plug.

19. The image sensor of claim 18, wherein the pixel transistor comprises a pixel gate electrode on an active portion in the second semiconductor substrate, wherein the upper connection pattern contacts a first surface of the through plug and a first surface of the pixel gate electrode.

20. The image sensor of claim 18, wherein the pixel transistor comprises a pixel gate electrode on an active portion in the second semiconductor substrate and source/drain regions at opposite sides of the pixel gate electrode, wherein the upper connection pattern contacts a first surface of the through plug and a first surface of one of the source/drain regions.
